(19) United States
(12) Patent Application Publication
(10) Pub. No.: US 2015/0008465 A1
(43) Pub. Date: Jan. 8, 2015

(54) REFLECTIVE ELECTRODE STRUCTURE, LIGHT EMITTING DEVICE AND PACKAGE

(71) Applicant: INVENLUX CORPORATION, EL MONTE, CA (US)

(72) Inventors: MARIO FERNANDO SAENGER NAYVER, EL MONTE, CA (US); WILLIAM SO, JR., EL MONTE, CA (US)

(21) Appl. No.: 14/323,892

(22) Filed: Jul. 3, 2014

Related U.S. Application Data
(60) Provisional application No. 61/843,861, filed on Jul. 8, 2013.

(51) Int. Cl. H01L 33/40; H01L 33/38

(52) U.S. Cl. CPC H01L 33/405; H01L 33/38
USPC 257/98

(57) ABSTRACT

The present invention describes a buried reflective electrode with vias and mesh current spreader isolated by a reflective stack of dielectric layers (BREVMIRS). The BREVMIRS includes a reflective stack of dielectric layers, a conducting mesh, a transparent conducting layer and a first electrode layer with vias going through the stack of reflective dielectric layers, the conducting mesh and the transparent conducting layer. There is at least one via going through the conductive reflective mesh and transparent conducting electrode. The BREVMIRS may be integrated into semiconductor light emitting diode devices to improve the device efficiency and light output power.

### CROSS-REFERENCE TO RELATED APPLICATION

This application claims the priority benefits of U.S. provisional application Ser. No. 61/843,861, filed on Jul. 8, 2013. The entirety of each of the above-mentioned patent applications is hereby incorporated by reference herein and made a part of this specification.

### BACKGROUND OF THE INVENTION

1. Field of the Invention

This invention relates to light emitting diode technology and, more particularly, to a highly reflective electrode structure for LEDs with flip chip structure, to LEDs using the reflective electrode structure and to a package for the LEDs using the reflective electrode structure, and to a method of making the same,

2. Background

Light emitting diodes are optoelectronic devices capable of converting an electric current into electromagnetic radiation such as visible light. Light is generated in the light emitting layer of the LED where electron-hole recombination takes place. Light emitting diodes are recognized as high efficiency luminous sources with long lifetime and high reliability. Depending on the conditions LEDs can be produced at low cost. These characteristics, along with the absence of toxic materials such as mercury make LEDs an attractive source of light around the world due to the potential energy savings and lower environmental impact.

Typical white LEDs consist of a blue light emitting diode with emission wavelength near 455 nm, accompanied by a phosphor that converts part of the blue emitted light into yellow light. This combination of blue and yellow light is perceived as white by the human eye, making it useful for illumination purposes. The amount of white light generated by such a white LED is measured in lumens and is proportional to the blue light output power or LOP, measured in watts. The LOP of an LED is calculated as the product of the internal quantum efficiency (IQE) multiplied by the light extraction efficiency (LEE), the electrical current and the photon energy.

In order for LEDs to reach a widespread use replacing conventional lighting sources, it is desired that LEDs can deliver a higher amount of lumen output relative to the cost of the LED, commonly referred to as lumen per dollar or 1 m/$. For this, one can design LEDs which have a higher IQE and LEE, therefore higher LOP. One can also design LEDs that can reduce manufacturing costs and another option is to operate LEDs at higher current density by increasing the driving current. The difficulty of achieving a high 1 m/$ by increasing the driving current is that the IQE of typical LEDs depends on current density and temperature at the light emitting layer.

The low LEE of typical LEDs is caused by the high index of refraction of the semiconductor materials where the light is generated, which causes total internal reflection of the emitted light. The light is reflected inside the LED multiple times, such that even a small absorption for a single pass of light can produce large losses causing less light to exit, therefore reducing the LOP and increasing the device temperature.

FIG. 1 shows the IQE in dependence of the current density for a typical LED at a junction temperature of 20 and 100° C. The current density dependence of the IQE involves a monotonic increase starting from zero to a maximum IQE level at about 4 A/cm², then an effect commonly known as current-dependent droop takes place. With the current dependent droop the IQE monotonically decreases causing a lower efficiency at higher current densities and generating more heat. For this reason it is necessary to design an LED such that the area of the active region occupies as much as possible the available area of the chip in order to decrease the current density and minimize the current-dependent droop. In addition to the current-dependent droop, the thermal-droop causes the IQE to deteriorate with increasing temperature as shown in FIG. 1. Therefore, it is desirable to minimize the thermal resistance of the LED such that the LED can efficiently dissipate the generated heat and minimize the thermal droop when operated at higher current densities.

Typical LEDs are operated in a current density range higher than 4 A/cm² usually near 35 A/cm² depending on the design and application, where higher operating currents are desirable but usually limited by the thermal resistance and the current density droop.

The typical structure of a lateral LED grown on a native substrate includes a n-type semiconductor layer, a light emitting layer, a p-type semiconductor layer, a transparent conducting layer, and first and second electrodes. The LEE of typical lateral LEDs can be improved with thicker substrates or by shaping the substrate with particular features like inclined side walls to provide a higher probability for the light to be extracted through the side surfaces of the native substrate. However, in the case of sapphire, the thermal resistance of the native substrate is relatively high, which creates a compromise between LEE and thermal resistance. In addition, the LED is attached to a submount with a heat conducting epoxy that has a low reflectivity and, therefore, reduces the LEE. To solve this problem, a dielectric mirror is usually formed adjacent to the sapphire lower surface to improve the reflectivity, which further increases the thermal resistance.

One approach to minimize the thermal resistance of the LED is to use a flip chip structure, where a lateral chip is flipped and attached with the p-type semiconductor layer adjacent to the second electrode facing towards a submount structure, contrary to the light emission direction. With this approach the thermal resistance of the native substrate can be removed from the thermal path. This approach makes use of the second electrode as a metal based mirror providing double function as reflector and also current spreader. The problem with metal based mirrors is that the averaged reflectivity over all angles of incidence is typically lower than 90% at a wavelength of 455 nm, causing more than 10% in optical losses every time light is reflected. Some examples of flip chip designs based on metallic mirrors include: U.S. Pat. Nos. 6,278,136 B1, 6,521,914 B2, 6,828,596 B2, 6,969,874 B1, 7,786,498 B2, 7,964,881 B2, 7,985,976 B2, 8,008,683 B2, US patent application publication No. 2007/0114564.

In order to improve the reflectivity of metallic mirrors for a flip chip LED, a popular approach is to use an omnidirectional reflector (ODR). The ODR has a higher reflectivity than a metal because of the total internal reflection caused by the contrast of high refractive index of the semiconductor material and low index dielectric layer. However, one problem of this type of structures as used in US patent application publication No. 2007/0170596 A1 is that a large part of the active region area needs to be sacrificed in order have an electrode large enough to be directly bonded to a pre-printed submount.

In another approach to achieve high LEE and low thermal resistance, there is the thin film flip chip LED with vertical structure. The hybrid mirror used in this type of LED structure requires the attachment of an electrode over the light emitting layer, blocking the light emitted under the electrode and typically require a current blocking layer, as described in US patent application publication No. 2011/0049546, U.S. Pat. Nos. 8,017,963 B2 and 7,622,746 B1, U.S. Pat. No. 7,915,629 B2, U.S. Pat. Nos. 7,420,218 B2 and 7,592,637 B2, and U.S. Pat. No. 8,026,527 B2.

All of the above mentioned patents and patent application publications are incorporated herein by reference in their entirety.

### SUMMARY OF THE INVENTION

A first aspect of the present invention provides a buried reflective electrode with vias and mesh current spreader isolated by a reflective stack (BREVMIRS). BREVMIRS is particularly well-suited for use in solid state light emitting devices such as light emitting diodes due to the efficient use of maximum active region area, very high mirror reflectivity, low thermal resistance, uniform current spreading and low cost. The BREVMIRS includes a transparent conducting layer, a conducting mesh, a reflective mesh, a reflective stack of dielectric layers and a reflective electrode layer, with first type vias extending from one surface of the reflective electrode layer through the conducting mesh, the reflective mesh, the reflective stack of dielectric layer and the transparent conducting layer.

The cross section area or width of the metallic fingers that form the conducting and reflective mesh varies depending on the amount of electrical current flowing through a given location in order to have a uniform current density distribution across the light emitting device,

The first type vias are located nearly at the center of each opening of the conducting and reflective mesh.

The transparent conductive layer, the reflective stack of dielectric stack layers, and the first electrode layer form a mirror that can have a reflectivity greater than 95 percent when averaging over all angles of incidence at 455 nm.

A second aspect of the present invention provides a BREVMIRS LED “type-A” with first and second electrodes on the same side of the light emitting device.

The light emitting device including a native substrate, a buffer layer, a first semiconductor layer, a light emitting layer, a second semiconductor layer, a conducting mesh, a reflective mesh, a transparent conductive layer, a first and second type vias, a first and second electrode layers, and a first and second conductive bonding layers.

The buffer layer is sandwiched between the native substrate and the first semiconductor layer. The light emitting layer overlies the first semiconductor layer; the light emitting layer generates light when electrons and holes recombine therein. The second semiconductor layer overlies the light emitting layer, the second semiconductor layer having a first surface in contact adjacent to the light emitting layer and a second surface in contact adjacent to a transparent conductive layer. The transparent conducting layer is adjacent to the second semiconductor material. The reflective mesh is adjacent to the transparent conducting layer. The conducting mesh is adjacent the reflective mesh, on the opposite side to the transparent conducting layer and partially covering the reflective mesh. The conducting mesh, the reflective mesh, the transparent conducting layer and the semiconductor layers are covered by a reflective stack of dielectric layers that have a very high reflectivity to the light generated by the light emitting layer such as greater than 95 percent when averaging over all angles of incidence at 455 nm. The reflective stack of dielectric layers overlies the first and second electrodes. The first and second electrodes are formed at the same time and on the same side of the light emitting device adjacent to the stack of dielectric layers. The first and second electrodes have a highly reflective surface on the side towards the light emitting layer. The first and second conductive bonding layers are formed adjacent to the surface contrary to the light emitting direction of the first and second electrodes.

The first electrode is connected to the first semiconductor layer by one or more first type vias passing through the reflective stack of dielectric layers, the transparent conducting layer, light emitting layer, and first and second semiconductor layers.

The second electrodes are connected to the electrically conducting mesh by one or more second type vias through the stack of reflective dielectric layers and the transparent conducting layer.

A third aspect of the present invention provides a BREVMIRS LED “type-A” without native substrate and with the outermost surface of the buffer layer being textured.

A fourth aspect of the present invention provides a semiconductor light emitting package intended for a BREVMIRS LED “type-A” with both contacts on the same side of the light emitting device including: an insulating submount, a first submount electrode and a second submount electrode formed at an upper surface thereof; an insulating underfill on the upper surface separating the first and second submount electrodes; a support pad, a first type bottom electrode and a second type bottom electrode formed on a lower surface thereof; and a first type submount via and a second conductivity type submount via going through the insulating submount connecting the first and second submount electrodes and the first and second type bottom electrodes, respectively.

A fifth aspect of the present invention provides a BREVMIRS LED “type-B” with first and second electrodes on different sides of the light emitting device. The light emitting device includes a buffer layer with textured outer most surface, a first semiconductor layer, a light emitting layer, a second semiconductor layer, a transparent conducting layer, a conducting mesh, a reflective mesh, a reflective stack of dielectric layers, one or more first type vias, a first electrode, a first conductive bonding layer, and a conductive substrate.

The buffer layer overlies the first semiconductor layer. The outermost surface of the buffer layer includes a textured outer most surface that is decorated with periodic or randomly distributed features. The first semiconductor layer overlies the light emitting layer; the light emitting layer generates light when electrons and holes recombine therein. The light emitting layer overlies the second semiconductor layer and the transparent conducting layer overlies the second semiconductor layer. The reflective mesh is adjacent to the transparent conducting layer. The conducting mesh in adjacent to the reflective mesh, on the opposite side than the transparent conducting layer and the conducting mesh is partially covering the reflective mesh. The transparent conducting layer, the light emitting layer lamination holes, the conducting and the reflective mesh are covered by a reflective stack of dielectric layers that have a very high reflectivity to the light generated by the light emitting layer. The reflective stack of dielectric layers overlies the first electrode. The first electrode has a highly reflective surface on the side towards the light emitting layer. The first semiconductor layer is electrically connected to the first electrode by a first type via going through the reflective stack of dielectric layers and the transparent conducting layer. The first type reflective electrode is in electrical contact with a first conductive bonding layer. The conductive bonding layer may be formed of a eutectic material that holds together the first electrode layer and the conductive substrate in electrical ohmic contact.

Part of the reflective and or conducting mesh is exposed by forming still another via structure by partially removing the buffer layer, the first semiconductor layer, the light emitting layer, the second type semiconductor layer and the transparent conducting layer in one or more locations over the conducting mesh. The exposed region of the reflective and or conducting mesh may be used as second electrode to be connected to an external current source with a wire bonding method.

A sixth aspect of the present invention provides a semiconductor light emitting package intended for a BREVMIRS LED “type-B” with both contacts on different sides of the light emitting device. The semiconductor light emitting package includes: an insulating submount, a first and second submount electrodes formed on the upper surface thereof, a first and second type bottom electrodes connected to the first and second submount electrodes with a first and second submount vias going through the insulating submount, and a support pad at the lower part of the insulating submount. The first and second submount electrodes, as well as the first and second type bottom electrodes and the support pad, are separated by a predetermined distance.

A seventh aspect of the present invention provides a method for fabricating a buried reflective electrode with vias and mesh current spreader isolated by a reflective stack of dielectric layer (BREVMIRS) for a light emitting device. The method includes:

forming a first electrode layer having at least one first type via extending from one surface thereof; forming a reflective stack of dielectric layer over the first electrode layer;

forming a conducting mesh over the reflective stack; and

forming a transparent conducting layer over the conducting mesh;

wherein the first type via penetrates through the conducting mesh, the transparent conducting layer, and the reflective stack of dielectric layer, and the first type via is electrically insulated from the conducting mesh and the transparent conducting layer.

### BRIEF DESCRIPTION OF THE DRAWINGS

FIG. 1 depicts the relationship of the internal quantum efficiency in dependence of the current density for a typical GaN based light emitting diode at 20 and 100 degrees Celsius.

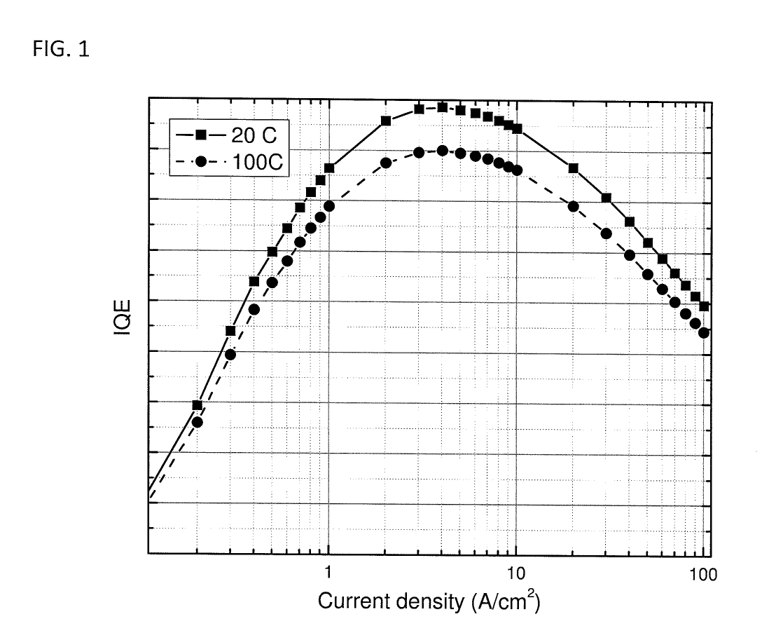

FIG. 2A shows the relationship of the reflectivity for light with a wavelength of 455 nm in dependence of the angle of incidence in GaN ambient for a hybrid, a silver/nickel and a silver/nickel/ITO mirror.

FIG. 2B shows the layer structure for the hybrid mirror reflectivity shown in FIG. 2A.

FIG. 3A shows a cross section view illustrating the structure of a BREVMIRS electrode structure according to an embodiment of the present invention.

FIG. 3B shows a cross section view illustrating the structure of a BREVMIRS electrode structure according to another embodiment of the present invention.

FIG. 4 shows an exploded view of a BREVMIRS LED “type-A” having first and second electrodes on the same side of the LED according to an embodiment of the present invention.

FIG. 5 shows a top view of a BREVMIRS LED “type-A” as seen from the light emitting direction according to an embodiment of the present invention.

FIG. 5A is a cross section of the BREVMIRS LED “type-A” according to FIG. 5 as seen along line A.

FIG. 5B is a cross section of the BREVMIRS LED “type-A” according to FIG. 5 as seen along line B.

FIG. 5C is a cross section of the BREVMIRS LED “type-A” according to FIG. 5 as seen along line C.

FIG. 6 shows a schematic drawing of BREVMIRS LED “type-A” without substrate according to another embodiment of the present invention.

FIG. 7 shows a top view schematic drawing of an BREVMIRS LED “type-A” attached to a package according to another embodiment of the present invention as seen from the light emitting direction.

FIG. 7A is a cross section of BREVMIRS LED “type-A” attached to a package according to FIG. 7 seen along line AA′.

FIG. 7B is a cross section of the BREVMIRS LED “type-A” attached onto a semiconductor light emitting device package according to FIG. 7 seen along line BB′.

FIG. 8 shows an exploded view of a BREVMIRS LED “type-B” having first and second electrodes on the different sides of the LED.

FIG. 9 shows a top view of a BREVMIRS LED “type-B” according to FIG. 8 as seen from the light emitting direction.

FIG. 9A is a cross section of the BREVMIRS LED “type-B” according to FIG. 9as seen along line AA′.

FIG. 10 is a cross section of the BREVMIRS LED “type-B” according to FIG. 9 attached to a package according to another embodiment of the present invention.

FIG. 11 is a cross sectional view of a partial structure of a wafer according to an embodiment of the present invention, showing the process steps.

FIG. 12 is a cross sectional view of a substrate having a complex semiconductor based heterostructure and a transparent conducting layer forming an ohmic contact with the second semiconductor layer.

FIG. 13 is a cross sectional view of a substrate having a complex semiconductor based heterostructure, and a partially etched transparent conducting layer forming an ohmic contact with the second semiconductor layer.

FIG. 14 is a cross sectional view of a substrate having a complex semiconductor based heterostructure, a partially etched transparent conducting layer forming an ohmic contact with the second semiconductor layer, and a conducting mesh.

FIG. 15 is a cross sectional view of a substrate having a mesa-etched complex semiconductor based heterostructure, a partially etched transparent conducting layer forming an ohmic contact with the second semiconductor layer, a reflective mesh and a conducting mesh.

FIG. 16 is a cross sectional view of a substrate having a mesa-etched complex semiconductor based heterostructure, a partially etched transparent conducting layer forming an ohmic contact with the second semiconductor layer, a reflective mesh, a conducting mesh and a stack of dielectric layers.

FIG. 17 is a cross sectional view of a substrate having a mesa-etched complex semiconductor based heterostructure, a partially etched transparent conducting layer forming an ohmic contact with the second semiconductor layer, a reflective mesh, a conducting mesh, and an etched stack of dielectric layers partially exposing the first semiconductor layer and the conducting mesh.

FIG. 18 is a cross sectional view of a substrate having a mesa-etched complex semiconductor based heterostructure, a partially etched transparent conducting layer forming an ohmic contact with the second semiconductor layer, a reflective mesh, a conducting mesh, a partially etched stack of dielectric layers, a first and second reflective electrode layer with vias covered by a solder material.

FIG. 19 is a cross section of BREVMIRS LED “type-A” without native substrate and with texture on the outer surface of the buffer layer attached to a package according to FIG. 7, as seen along line AA′.

FIG. 20 is a cross sectional view of a substrate having a mesa-etched complex semiconductor based heterostructure, a partially etched transparent conducting layer forming an ohmic contact with the second semiconductor layer, a reflective mesh, a conducting mesh, and an etched stack of dielectric layers partially exposing the first semiconductor layer.

FIG. 21 is a cross sectional view of a substrate having a mesa-etched complex semiconductor based heterostructure, a partially etched transparent conducting layer forming an ohmic contact with the second semiconductor layer, a reflective mesh, a conducting mesh, a partially etched stack of dielectric layer, a first reflective electrode layer with vias covered by a solder material.

FIG. 22 is a cross sectional view of a substrate having a mesa-etched complex semiconductor based heterostructure, a partially etched transparent conducting layer forming an ohmic contact with the second semiconductor layer, a reflective mesh, a conducting mesh, a partially etched stack of dielectric layer, and a first reflective electrode layer bonded by a solder material to a conductive substrate.

FIG. 23 is a cross sectional view of a mesa-etched complex semiconductor based heterostructure with the substrate removed and textured outer surface of the buffer layer, a partially etched transparent conducting layer forming an ohmic contact with the second semiconductor layer, a reflective mesh, a conducting mesh, a partially etched stack of dielectric layer, and a first reflective electrode layer bonded by a solder material to a conductive substrate.

### DETAILED DESCRIPTION OF THE EMBODIMENTS

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art.

Throughout the specification, like reference numbers represent like components. The terms “first semiconductor” and “second semiconductor” refer to two semiconductors having different kind of electrical conducting mechanisms. As used herein, first semiconductor represents n-type conductivity semiconductor and second semiconductor represents p-type conductivity semiconductor unless otherwise specified.

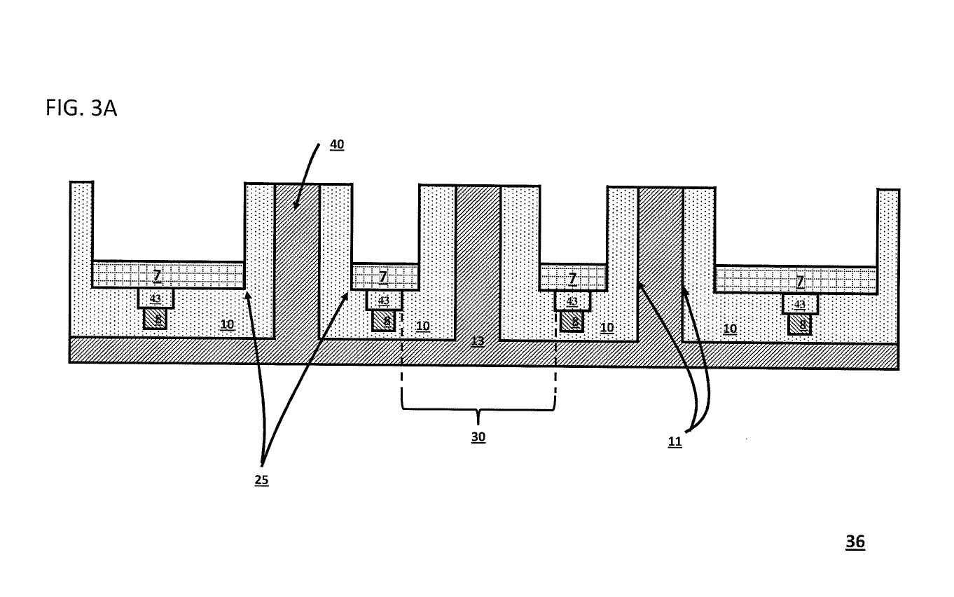

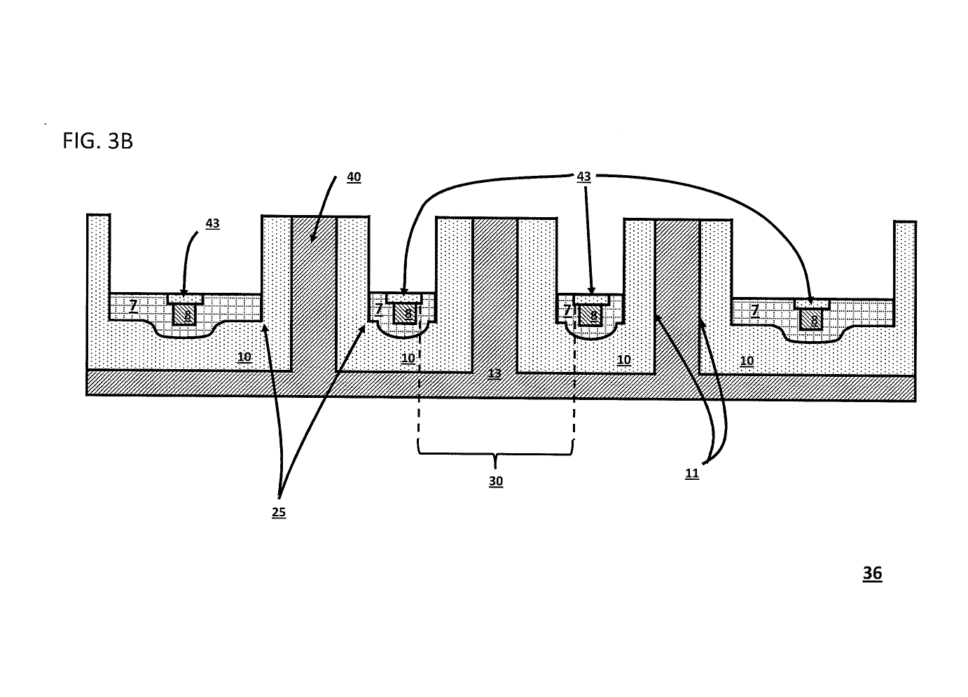

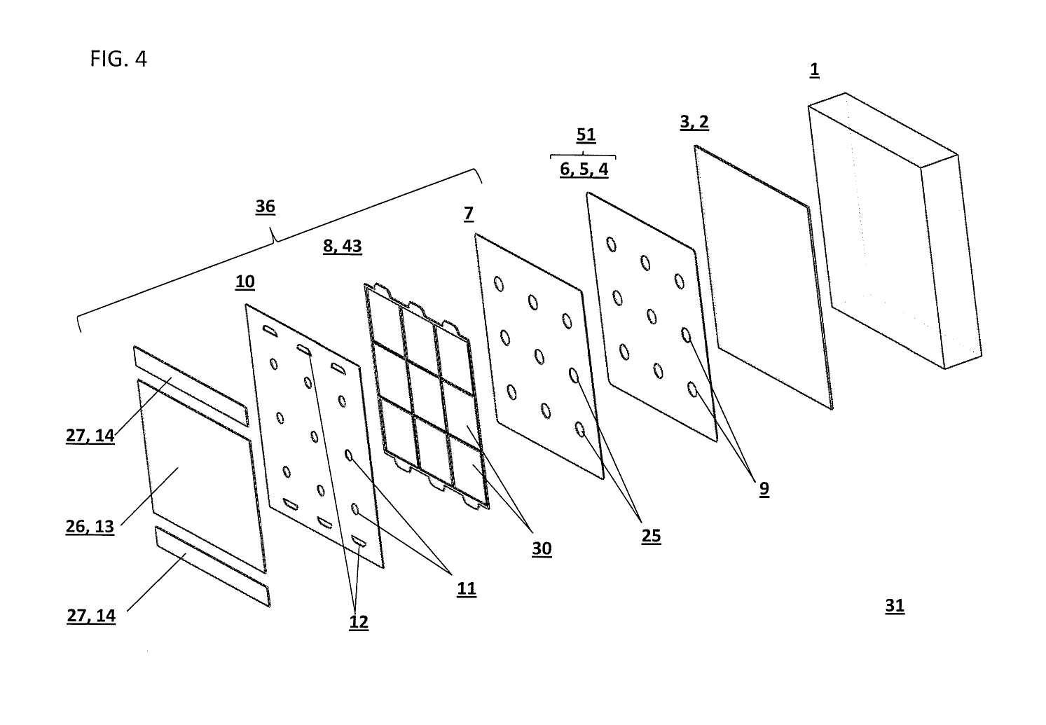

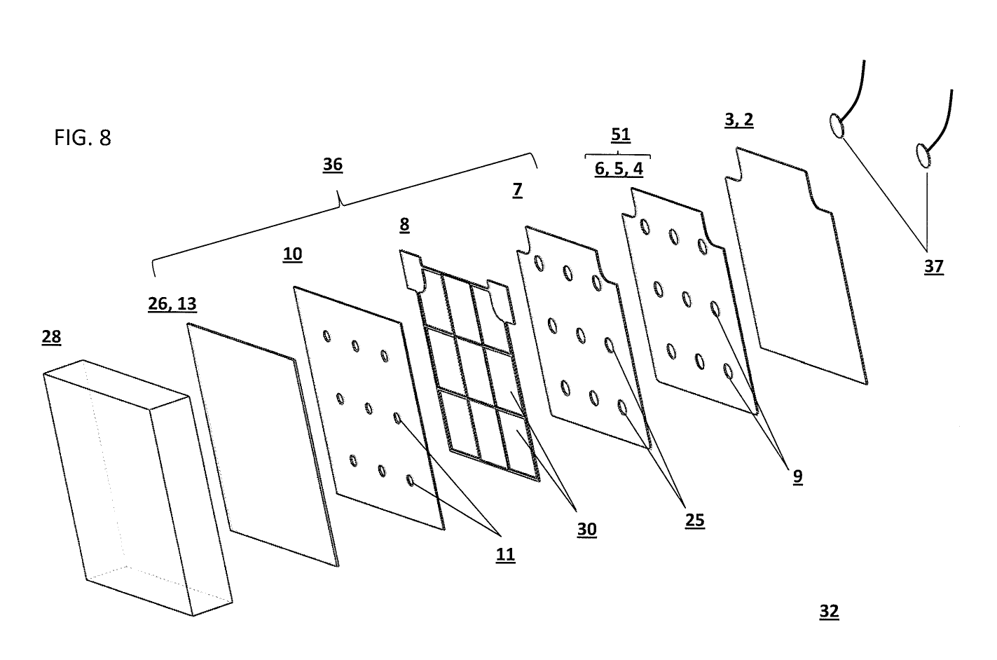

FIG. 3A is a cross section view of a buried reflective electrode with vias and mesh current spreader isolated by a reflective stack 36 (BREVMIRS) (also see FIGS. 4 and 8) according to an exemplary embodiment of the invention. A first electrode layer 13 with first type vias 40 extending from one surface of the first electrode layer 13 is provided. A reflective stack of dielectric layers 10 is provided over the reflective first electrode layer 13 with the first type vias 40 and also surrounds the first type vias 40. The entire sidewalls of the first type vias 40 are surrounded by the reflective stack of dielectric layers 10 except for the cap of vias 40, which is left without dielectric cover. The reflective stack of dielectric layers 10 is composed of an alternating sequence of low absorption or transparent dielectric layers with a first and a second index of refraction with predetermined thicknesses. A reflective mesh 43 and a conducting mesh 8 are located around the first type vias 40, separated by a predetermined distance and electrically insulated from the first electrode layer 13 by the reflective stack of dielectric layers 10. Both the reflective mesh 43 and the conducting mesh 8 are sandwiched in between the reflective stack of dielectric layers 10 and a transparent conducting layer 7. The reflective mesh 43 is electrically connected to the transparent conducting layer 7 and to the conducting mesh 8. The transparent conducting layer 7 lies in a plane parallel to the first electrode layer 13. The transparent conducting layer 7, the reflective mesh 43 and the conducting mesh 8 are electrically insulated from the first electrode layer 13 and the first type vias 40 by the reflective stack of dielectric layers 10. The percentage ratio of the area covered by the conducting mesh 8 to the area of the transparent conducting layer 7 as viewed from a vertical direction (i.e., layer growth direction) can be about 1%-70%, such as 10% to 20%.

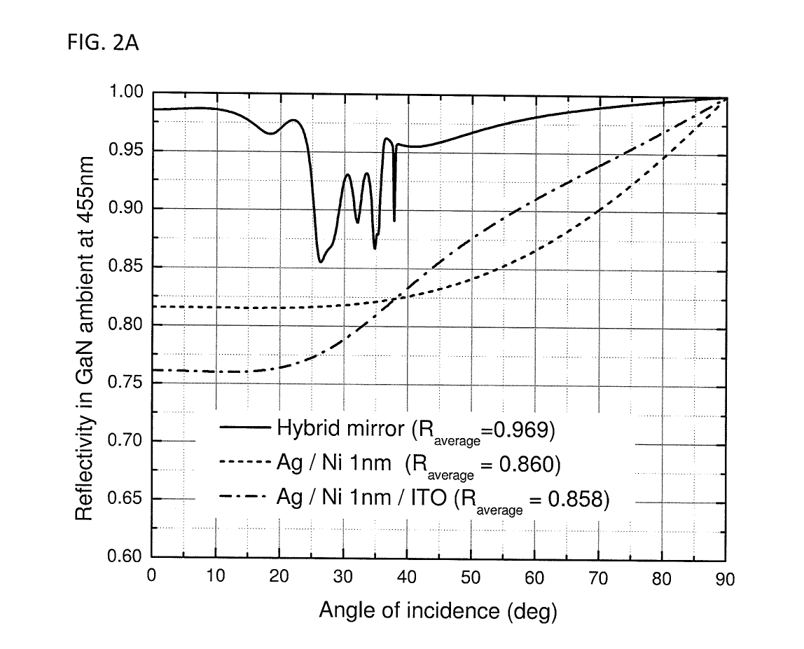

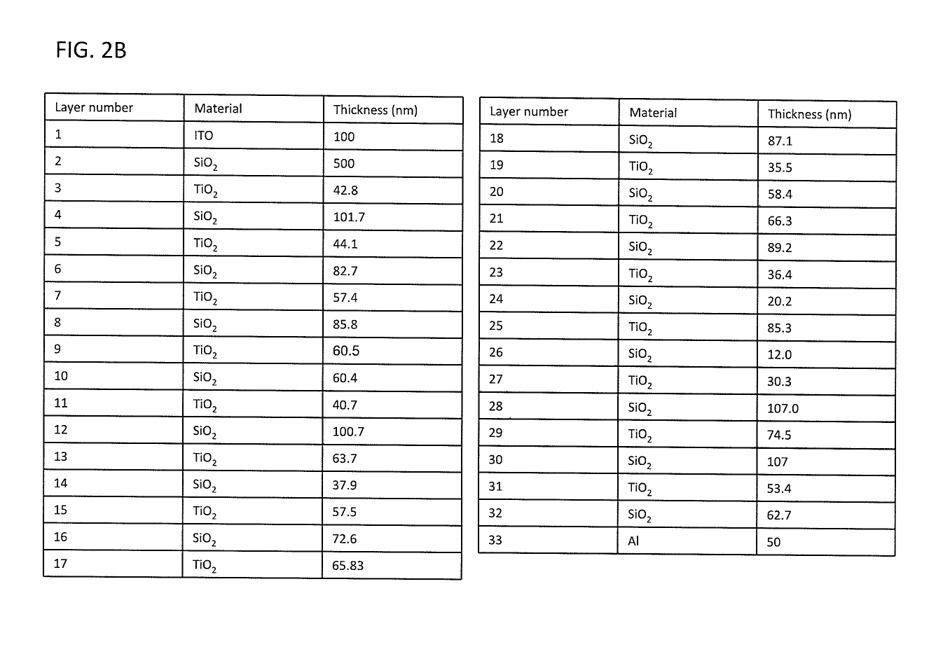

FIG. 2A depicts the reflectivity of a silver/nickel, a silver/nickel/ITO and a hybrid mirror formed by silver/stack of dielectric layers/ITO in dependence of the angle of incidence in a GaN ambient (refractive index of GaN, nₒ=2.48) for a wavelength of 455 nm. The corresponding structure for the hybrid mirror as shown in FIG. 2A, is provided in FIG. 2B, where the first layer in contact with the semiconductor material or GaN is the transparent conducting layer 7. The optical constants at 455 nm of the transparent conducting layer 7, the SiO₂ and the TiO₂ used for the calculated reflectivity spectrum shown in FIG. 2 are derived from ellipsometry and transmission measurements, where n_{SiO2}=1.47, n_{TiO2}=2.44, k_{SiO2}=k_{TiO2}=0, n_{TCL}=2.05, k_{TCL}=. The optical constants for the metals are obtained from literature values n_{Al}=, k_{Al}=, n_{Ag}=, k_{Ag}=, n_{Ni}=, k_{Ni}=.

It can be clearly observed that the reflectivity of a hybrid mirror is higher than that of a silver/nickel mirror. Therefore, the use of a hybrid mirror has the potential to improve the LEE. Given the insulating quality of the dielectric layers, it is desirable a mirror and electrode arrangement that provide high reflectivity, low thermal resistance, maximum active region, have no electrode coverage of the active region, and that can be realized reliably at low cost.

Regarding the area covered by reflective mesh 43 and conducting mesh 8 mesh, a lower percentage ratio of the area of conducting mesh 8 to the area of the transparent conducting layer 7 is preferred given that the reflectivity of the reflective mesh 8 is still lower than that of the hybrid mirror formed by the reflective stack of dielectric layers 10, the transparent conducting layer 7 and the electrode layers 13, 14, located at the mesh openings 30. Therefore, as long as the electrical conducting function can be served, the ratio can be lower than 10%, for example, 5% to 10%.

The first type vias 40 go through corresponding first type openings 11 in the reflective stack of dielectric layers 10, also through holes 25 in the transparent conducting layer 7 and through the mesh openings 30.

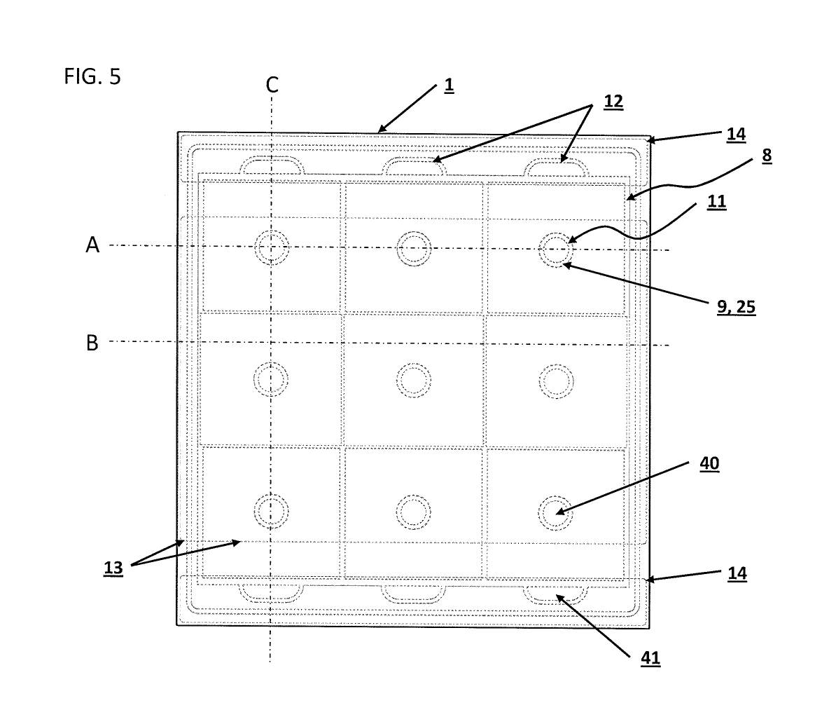

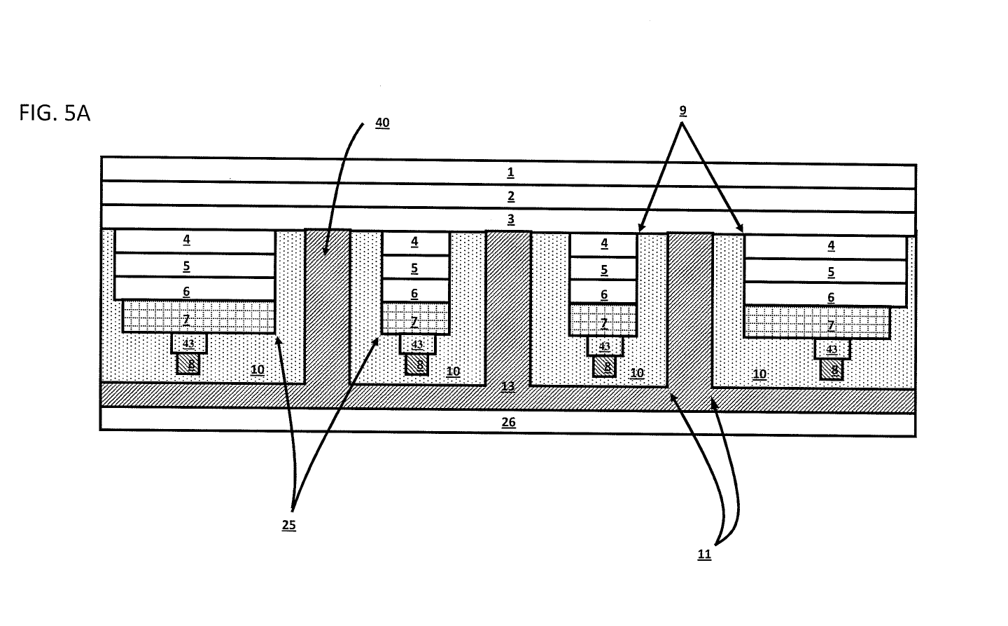

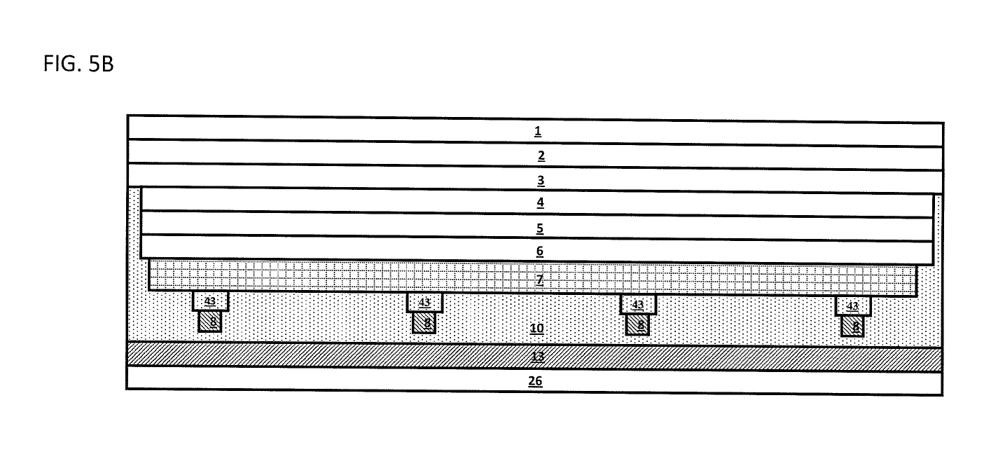

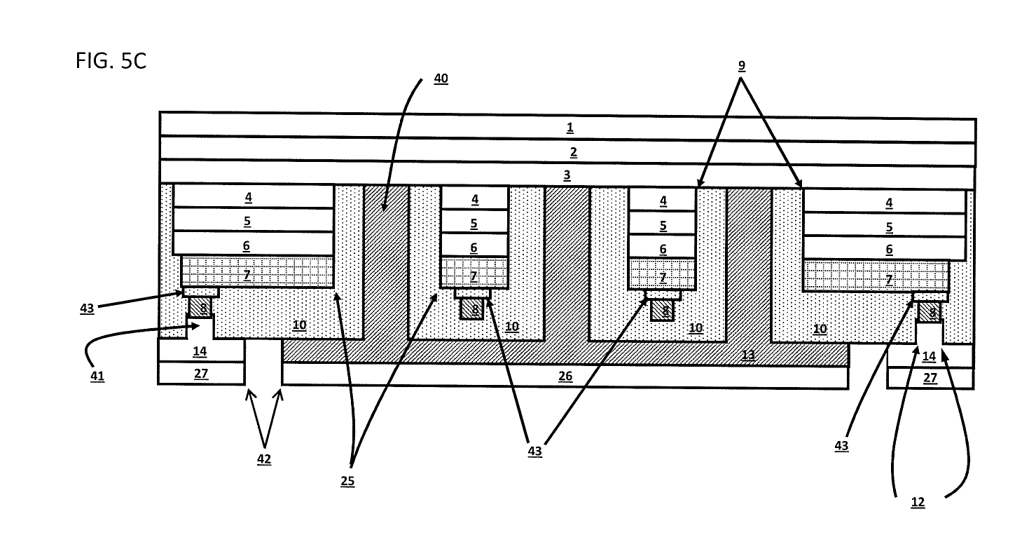

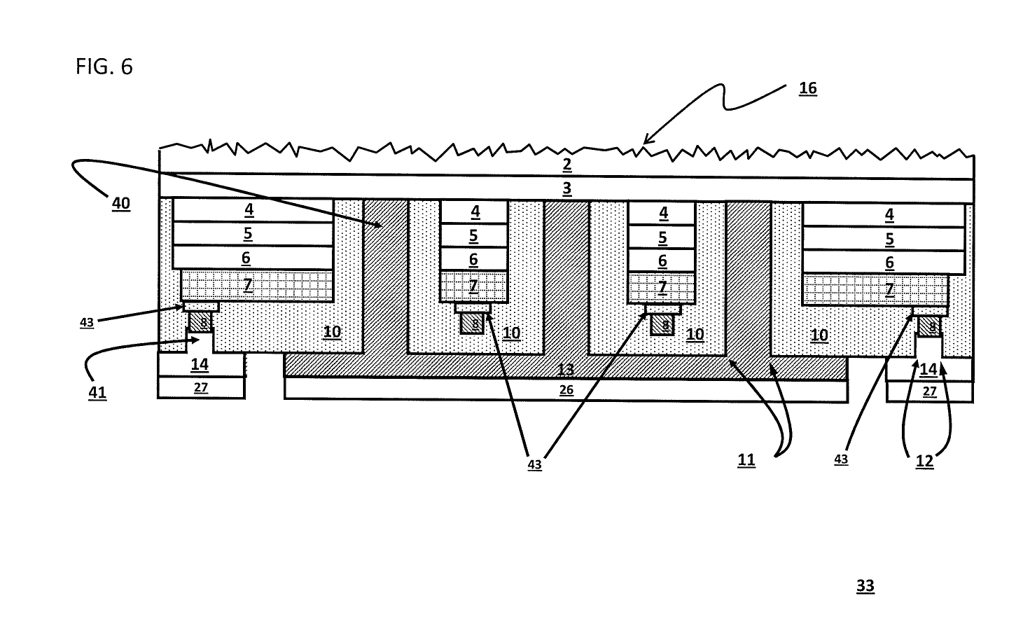

FIG. 3B is a cross section view of a BREVMIRS according to another embodiment of the present invention. The only difference to the BREVMIRS shown in FIG. 3B is that the conducting mesh 8 is no longer sandwiched in between the transparent conducting layer 7 and the reflective stack of dielectric layers 10. Instead, the conducting mesh 8 is surrounded by the transparent conducting layer 7 on all surfaces except for the upper surface facing towards the reflective mesh 43. In other words, reflective mesh 43 and conducting mesh 8 are imbedded in the transparent conducting layer 7 with the upper surface of reflective mesh 43 being exposed. FIG. 4 shows an exploded view illustrating a BREVMIRS LED “type-A” 31, which includes a semiconductor light emitting device with a BREVMIRS 36 as described in FIG. 3A with first and second electrodes on the same side, in accordance with an embodiment of the present invention. FIG. 5 shows a schematic drawing of the semiconductor light emitting device shown in FIG. 6 as seen from the light emitting direction (here it is defined as the top side of the semiconductor light emitting device). Hereinafter, a description will be made with reference to FIGS. 4 and 5.

A BREVMIRS LED “type-A” 31 according to an exemplary embodiment of the invention includes a native substrate 1, a buffer layer 2, a first semiconductor layer 3, a first semiconductor layer with holes 4, a light emitting layer 5, a second semiconductor layer 6, a transparent conducting layer 7, a conducting mesh 8, a reflective mesh 43, a reflective stack of dielectric layers 10, a first electrode layer 13, and a second electrode layer 14 that are sequentially laminated. In this embodiment, the reflective stack of dielectric layers 10 contains at least one first type opening 11 (nine first type openings are shown in FIG. 4) and at least one second type opening 12 (six second type openings are shown in FIG. 4). The second electrode layer 14 is electrically connected to the conducting mesh 8 by a second type via 41 passing through the second type opening 12 in the reflective stack of dielectric layers 10. The conducting mesh 8 is electrically connected to the reflective mesh 43, the reflective mesh 43 is electrically connected to the transparent conducting layer 7, and the transparent conducting layer 7 is electrically connected to the second semiconductor layer 6. In the BREVMIRS LED “type-A” 31, the first semiconductor layer with holes 4, the light emitting layer 5, and the second semiconductor layer 6 perform light emission. Hereinafter, they are referred to as light emitting lamination 51.

The native substrate 1 can be made of any material known in the art suitable for LED, such as sapphire or silicon carbide. The buffer layer 2 is deposited on the native substrate 1 to facilitate the deposition of the subsequent semiconductor layers. The buffer layer 2 is utilized to reduce the stress and/or strain (e.g., due to thermal or lattice mismatch between native substrate and first semiconductor layer 3 and the light emitting lamination 51) so as to reduce unwanted defects in the semiconductor heterostructure. Buffer layer 2 typically has a single crystal structure and can made of undoped or n-doped GaN, such as unintentionally doped GaN.

Each of the layers forming the light emitting lamination 51 may be made of any suitable semiconductor known in the art, such as a GaN-based semiconductor, a ZnO-based semiconductor, a GaAs-based semiconductor, a GaP-based semiconductor, and a GaAsP-based semiconductor as known in the art. The light emitting lamination 51 may be formed by using, for example, metal organic chemical vapor deposition (MOCVD), or any other conventional methods known to the art. In addition, each of the semiconductor layers 4, 5, 6 may be made of any one of III-nitride semiconductor, an II-VI semiconductor, and Si. Each of the semiconductor layers forming the light emitting lamination 51 is formed by doping the above-described semiconductor with appropriate impurities in consideration of the conductivity type.

The first semiconductor layer 3 is connected to first electrode layer 13 (for example a cathode layer) for current spreading and supplying charges to first semiconductor layer 4. Preferably, the first semiconductor layer 3 has a larger energy band than the light emitting layer 5. The first semiconductor layer 3 can be made of any material know in the art suitable to serve this purpose such as silicon doped n-type GaN. The light emitting layer 5 is a layer where light emission takes place when electrons and holes recombine. The light emitting layer 5 is formed of a material that has a smaller energy band gap than each of the first semiconductor layers 3 and 4, and the second semiconductor layer 6. For example, when each of the first semiconductor layers 3 and 4 and the second semiconductor layer 6 is formed of a GaN based semiconductor, the light emitting layer 5 may be formed by using an III-V based semiconductor that has a smaller energy band gap than GaN. That is, the light emitting layer 5 may be made of InₓAl_{y}Ga_{(1-x-y)}N (0≦x≦1, 0≦y≦1, 0≦x+y≦1).

In consideration of characteristics of the light emitting layer 5, the light emitting layer 5 is preferably not doped with impurities. The wavelength of light emitted can be controlled by adjusting the mole ratio of constituents. Therefore, a semiconductor light emitting device with BREVMIRS 36 can emit any one of infrared light, visible light, and UV light according to the characteristics of the light emitting layer 5.

Each of the first and second electrode layers 13 and 14 is formed in order to apply a voltage to the same semiconductor layer. Therefore, in consideration of electro-conductivity, the first and second electrode layers 13 and 14 may be formed of metal. The second electrode layer 14 is connected to the conducting mesh 8, the conducting mesh 8 is connected to the reflective mesh 43, which is connected to the transparent conducting layer 7, which in turn is connected to the second semiconductor layer 6. The first electrode layer 13 is connected to the first semiconductor layer 3 by the first type via 40 insulatedly passing through the reflective stack of dielectric layers 10, the mesh opening 30, the transparent conducting layer 7, and the light emitting lamination 51. That is, the second semiconductor layer 6 can be electrically connected to an external current source (not shown) through the second electrode layer 14, the conducting mesh 8, the reflective mesh 43, and the transparent conducting layer 7. Similarly, an external current source (not shown) can be electrically connected to the first semiconductor layer 3 through the first electrode layer 13 and at least one first type via 40. The electrode layers 13 and 14 may be formed by a metal layer or a combination of metal layers, for example, Ag, W, Cr, Pt and Au. The first and second electrode layers 13 and 14 can be made of the same or different material. The first electrode layer 13 is electrically connected to the first semiconductor layer 3, and the second electrode layer 14 is electrically connected to the conducting mesh 8, where the conducting mesh 8 is electrically connected to the reflective mesh 43, which is connected to the transparent conducting layer 7 and the transparent conducting layer 7 is electrically connected to the second semiconductor layer 6. When the first conductivity type is n-type conductivity and the second conductivity type is p-type conductivity, the first electrode layer 13 is a cathode layer and the second electrode layer 14 is an anode layer.

Since the first and second electrode layers 13 and 14 are connected to different semiconductor layers, respectively, the first and second electrode layers 13 and 14 need to be separated by a predetermined distance, and electrically isolated from each other. In a similar fashion, the reflective stack of dielectric layers 10 serves as isolation between the first electrode layer 13 and the second semiconductor layer 6, the transparent conducting layer 7, and the conducting mesh 8. The reflective dielectric layer stack 10 may include a sequence of dielectric layers with very high electrical resistance, with alternating dielectric layers of high and low index of refraction, i.e. a dielectric layer of high refractive index is sandwiched between two dielectric layers of low refractive index and/or a dielectric layer of low refractive index is sandwiched between two dielectric layers of high refractive index. The reflective dielectric layer stack 10 may be formed of materials such as magnesium fluoride (MgF₂), silicon dioxide (SiO₂), niobium pentoxide (Nb₂O₅), niobium dioxide (NbO₂), and titanium dioxide (TiO₂), for example. The first layer of the reflective dielectric layer stack 10 adjacent to the transparent conducting layer 7 has a lower refractive index than the second semiconductor layer 6 at the wavelength emitted by the light emitting layer 5. In an embodiment, the dielectric layer of low refractive index of refraction is made of silicon dioxide (SiO₂) or magnesium fluoride (MgF₂), and the dielectric layer of high index of refraction is made of titanium dioxide (TiO₂), niobium pentoxide (Nb₂O₅), or niobium dioxide (NbO₂). The number and thickness of the alternating dielectric layers are not specifically limited as long as a reflective hybrid mirror can be formed by the transparent conducting layer 7, the reflective stack of dielectric layers 10, and the first and/or second electrode layers 13, 14. In an embodiment, the thickness of the dielectric layer with low refractive index of refraction can be in the range of 20 to 2000 nm, such as 100 to 1500 nm, or 200 to 500 nm, the thickness of the dielectric layer with high refractive index of refraction can be in the range of 20 to 80 nm, such as 30 to 70 nm, or 40 to 60 nm, and the total number of the alternating dielectric layers can be in the range of 2 to 50. Alternatively, the reflective stack of dielectric layers 10 can also be made of a single layer of the above mentioned dielectric material, preferable with an index of refraction lower than that of the second type semiconductor layer 6 at the wavelength emitted by the light emitting layer 5.

The transparent conducting layer 7, the reflective stack of dielectric layers 10, and the first and/or second electrode layers 13, 14 can form a hybrid mirror. The hybrid mirror may have an average reflectivity greater than 95% for the wavelength emitted by the light emitting layer. In an embodiment, the hybrid mirror has a structure of silver/stack of dielectric layers/ITO, where the transparent conducting layer 7 is made of ITO, the composition of the first and/or second electrode layers 13, 14 may include silver or aluminum as highly reflective material and gold as electrical conductor, and the reflective stack of dielectric layers 10 is made of a plurality of alternately arranged dielectric layers with a first index of refraction and a second index of refraction lower than the first index of refraction, respectively, where one dielectric layer with the first index of refraction is sandwiched between two dielectric layers with the second index of refraction, and/or one dielectric layer with the second index of refraction is sandwiched between two dielectric layers with the first index of refraction.

In an embodiment, the electrode layers 13 and 14 substantially covers the entire chip area, resulting a reflective hybrid mirror with as large area as possible to promote its reflective function. The first electrode layer 13 is positioned at the central part of the chip area, while the second electrode layer 14 is positioned at the peripheral part of the chip area. FIG. 4 shows that the second electrode layer 14 is formed by two strips parallely arranged on two edges of the chip area. Similarly, the transparent conducting layer 7 and the reflective stack of dielectric layers 10 are also made to substantially cover the entire chip area. Preferably, the surface of the first electrode layer 13 facing the reflective dielectric layer stack 10 (in this embodiment, it is in contact with the reflective dielectric layer stack 10), as well as the surface of the reflective mesh 43, have a very high optical reflectivity in order to reflect light generated from the light emitting layer 5. Therefore, the reflective mesh 43 in contact with the transparent conducting layer 7 may be formed of a highly reflective metal, for example, of a silver layer with a thin nickel barrier in between the silver and the transparent conducting layer 7, or of aluminum with a reflectivity as seen in FIG. 2A. The thickness of the reflective mesh 43 can be in the range from 1 to 1000 nm, such as from 5 to 200 nm, in particular from 5 to 50 nm. Since the direction in which the BREVMIRS LED “type-A” 31 emits light generated in the light emitting layer 6 is on the side of the buffer layer 2, then the first and second electrode layers 13 and 14, the reflective mesh 43, the reflective dielectric stack layers 10 and the transparent conducting layer 7 are on the other side contrary to the intended light emission direction. Light moving from the light emitting layer 5 in a direction contrary to the direction in which the BREVMIRS LED “type-A” 31 emits light needs to be reflected with high efficiency by the first and second electrode layers 13 and 14, the reflective mesh 43, the reflective stack of dielectric layers 10 and the transparent conducting layer 7, in order to increase the light extraction efficiency of the BREVMIRS LED “type-A” 31.

In order to efficiently reflect the light generated from the light emitting layer 5, preferably, the surface of the first and second electrode layer 13 and 14 interacting with light contains a metal with high reflectance. For example, for light emitted in the visible spectrum, the metal may be silver or aluminum.

The second type openings 12 in the reflective stack of dielectric layers 10 enable the electrical contact between the conducting mesh 8 and the second electrode layer 14, as further described in FIG. 5C. Similarly, the first type openings 11 in the reflective stack of dielectric layers 10 enable the electrical contact between the first semiconductor layer 3 and the first electrode layer 13, as further described in FIGS. 5A and 5C.

In FIG. 4, an example of first and second type openings 11 and 12 in the reflective stack of dielectric layers 10 is shown. In FIG. 5 it is possible to see that the first type opening 11 are concentric with hole 9 in the light emitting lamination 51 and hole 25 in the transparent conducting layer 7. In general, the size or dimension of the transparent conducting layer holes 25 is equal to or larger than that of the light emitting layer lamination holes 9. For example, when holes 25 and holes 9 have a circular shape, the diameter of holes 25 is equal to or larger than the diameter of holes 9. As shown in FIG. 4, the first and second electrode layers 13 and 14 are formed coplanar with each other. The first electrode layers 13 occupies the central part and the second electrode layer 14 occupies the periphery part, and the first and second electrode layers 13 and 14 substantially cover the entire transverse area of the LED structure shown in FIG. 4.

The light emitting lamination holes 9, the transparent conducting layer holes 25, and the first and second type openings 11 and 12 can be formed by selective etching. When forming the first and second type openings 11 and 12 in the reflective stack of dielectric layers 10, in general the reflective stack of dielectric layers 10 is etched until the first semiconductor 3 and the conducting mesh 8 are exposed for first and second type openings 11 and 12, respectively. Since the reflective stack of dielectric layers 10 provides electrical isolation between the first electrode layer 13 and the second semiconductor layer 6, as well as between the first electrode layer 13 and the transparent conducting layer 7 and the conducting mesh 8, the size of the light emitting lamination holes 9 can be equal to or larger than that of the first type openings 11. Since the first and second electrode layers 13 and 14 are on the same side of the BREVMIRS LED “type-A” 31 sharing the same plane, both electrodes can be formed at the same time.

The shape and the diameter of the first and second type openings 11 and 12, as well as the shape and diameter of the light emitting lamination holes 9 and transparent conducting layer holes 25 can be appropriately determined by those skilled in the art in consideration of the area of the light emitting layer 5, electrical connection efficiency, and current spreading in the transparent conducting layer 7 and first semiconductor layer 3 in according to this disclosure. The reflective stack of dielectric layers 10 includes at least one first type and at least one second type openings 11 and 12, respectively. The first and second type semiconductor layer 3 and 6 are electrically connected to the first and second electrode layers 13 and 14 through the first and second type openings 11 and 12, respectively in the reflective stack of dielectric layers 10. The first type opening 11 is filled by the first electrode layer 13 forming a first type via 40 which is electrically insulated from the second semiconductor layer 6 and the light emitting layer 5, and extends to at least the first semiconductor layer 3. The first type opening 11 can also be filled by the conductive material different from that of first electrode layer 13 to form the first type via 40. The first electrode layer 13 fills at least one first type opening 11 in order to connect the first semiconductor layer 3 to an external current source (not shown). The first type openings 11 are formed through the reflective stack of dielectric layers 10, and aligned with the corresponding light emitting lamination holes 9, the transparent conducting layer holes 25, and the center portions of corresponding mesh openings 30, and exposed to the first semiconductor layer 3.

The second type openings 12 are filled with the second electrode layer 14, thus forming a second type via 41 and providing electrical connection between the second electrode layer 14 and the conducting mesh 8. The second type openings 12 can also be filled with a conductive material different than that of second electrode layer 14 to forming the second type via 41. The second type via 41 is electrically insulated from the first electrode layer 13 by the stack of dielectric layers 10 and by an electrode separation 42.

The second electrode layer 14 fills at least one second type opening 12 in order to form a second type via 41 and provide electrical connection to the second semiconductor layer 6, which in turn is connected to the transparent conducting layer 7, the conducting mesh 8, the reflective mesh 43 and the second electrode layer 14, to an external current source (not shown). Further, the material of the first and second type via 40 and 41 can be an electrode material, for example, the same as that of the first and second electrode layers 13 and 14.

Since the first and second type openings 11 and 12 are used for the electrical connection, the first and second electrode layers 13 and 14 may include at least one via each, respectively. However, in order to uniformly spread a current that is transmitted to the first semiconductor layer 3 and conducting mesh 8, the first and second electrode layers 13 and 14 may include a plurality of first and second type vias 40 and 41 at predetermined positions, respectively. The first type vias 40 can be made of material same as or different from that of the first electrode layer 13, and the second type vias 41 can be made of material same as or different from that of the second electrode layer 14.

FIG. 5 is a plan view illustrating the BREVMIRS LED “type-A” 31 as seen from the light emitting direction. The first type openings 11 in the stack of dielectric layers 10, the holes 25 in the transparent conducting layer 7, and holes 9 in the light emitting layer lamination 51 are concentric or aligned and formed nearly at the center of each mesh opening 30. The size or diameter of the light emitting layer holes 9 and transparent conducting layer holes 25 is larger than the size or diameter of the corresponding first type openings 11 such that the first type via 40 is electrically insulated from the light emitting layer 5, the second type semiconductor layer 6, the transparent conducting layer 7, the reflective mesh 43 and the conducting mesh 8, when penetrating there through. The first type via 40 is positioned within the first electrode layer 13. As seen from the light emitting direction like in FIG. 5, the position of the second type openings 12 falls on the conducting mesh 8 and on the second electrode layer 14.

The reflective mesh 43 and the conducting mesh 8 contain a repetitive array of openings 30, with circular, rectangular, triangular or hexagonal shape, or any other shape. These openings 30 are defined by lines or wires which can be made by patterning and etching a reflective metal layer. It is also possible to make the width of the fingers forming the reflective 43 and conducting mesh 8 vary, being wider when approaching the second type opening 12 in order to make a more uniform current density distribution within the mesh. In general, the cross section area of fingers of the conducting mesh 8 can vary in such a way: the closer to an electrode to which the conducting mesh 8 is to be connected, the larger of the cross section area, so as to maintain a uniform current density within the mesh. The width can vary continuously or discontinuously, decreasing with distance away from the second type opening 12. In general, the width of the fingers of the reflective 43 and conducting mesh 8 can be in the range from 0.1 to 100 μm, such as 1 to 50 μm, 10 to 30 μm, the thickness of the lines of the conducting mesh 8 can be in the range from 0.1 to 20 μm, such as 1 to 15 μm, 5 to 10 μm, and the area of the opening 30 can be in the range from 1 to 1000 mil², such as 10 to 500 mil², 100 to 300 mil². Reflective 43 is preferably conformal with conducting mesh 8 and may have a thickness in the range from 0.1 to 20 μm, such as 1 to 15 μm, 5 to 10 μm. Each opening 30 can surround one or more holes 25 of the transparent conducting layer 7. Preferably, the reflective 43 and conducting mesh 8 cover substantially the entire chip area. The percentage of the transparent conducting layer 7 covered by the reflective 43 and conducting mesh 8, when viewed from the light emission direction, can be less than 60%, but more than 3%.

FIG. 5A is a schematic cross-sectional view illustrating the semiconductor light emitting device shown in FIG. 5, as seen along the line A. FIG. 5B is a cross-sectional view illustrating the semiconductor light emitting device, shown in FIG. 5, taken along the line B. FIG. 5C is a cross-sectional view illustrating the semiconductor light emitting device, shown in FIG. 5, as seen along the line C.

The line A is chosen in order to show a cross section of the BREVMIRS LED “type-A” 31 that includes first type openings 11 in the reflective stack of dielectric layers 10, light emitting lamination holes 9, transparent conducting layer holes 25, reflective 43 and conducting mesh 8. The line B is taken to show a cross section of the BREVMIRS LED “type-A” 31 that excludes first and second type openings 11 and 12. The line C is taken to show a cross section of the BREVMIRS LED “type-A” 31 that includes first and second type vias 40 and 41, first and second electrode layers 13 and 14, transparent conducting layer holes 25, and light emitting lamination holes 9. Hereinafter, the description will be described with reference to FIGS. 5A to 5C.

Referring to FIGS. 5A and 5C, the light emitting lamination 51 receives at least one first type via 40 and light emitting lamination hole 9, where the first type via 40 extrudes from one surface of the first electrode layer 13. The first type via 40 fills the channel formed by the first type opening 11 in the reflective stack of dielectric layers 10, going through the light emitting layer lamination hole 9 and the transparent conducting layer hole 25. The first type via 40 is electrically connected to the first semiconductor layer 3, electrically insulated from the light emitting layer 5 and the second semiconductor layer 6, and extends from one surface of the first electrode layer 13 to the first semiconductor layer 3. Therefore, the first type via 40 passes through the reflective stack of dielectric layers 10, the reflective mesh 43, the conducting mesh 8, and the light emitting lamination 51 extending up to the first semiconductor layer 3 or slightly cutting into the first semiconductor layer 3. Once the first type via 40 is electrically connected to the first semiconductor layer 3, the first type via 40 does not extend beyond the interface of the first semiconductor layer 3 and the buffer layer 2. The reflective stack of dielectric layers 10 serves as highly reflective mirror and electrically isolates the first electrodes 13 and the first type via 40 from the second semiconductor layer 6, the conducting mesh 8 and the transparent conducting layer 7. Light emitting lamination holes 9 are formed in light emitting lamination 51, penetrating the first semiconductor layer 4, the light emitting layer 5 and the second semiconductor layer 6. The ratio of the total area of the emitting lamination holes 9 to the total area of the light emitting lamination 51 can be in the range of 1% to 35%, such as 5% to 25%, or 10% to 15%.

The first type via 40 is used for the electrical connection and current spreading in the first semiconductor layer 3. Therefore, a predetermined number of first type vias 40 are formed, and each of the first type vias 40 has a cross-sectional area small enough to allow uniform current spreading in the first semiconductor layer 3.

The cross-sectional area and the amount of first type vias 40 need to be large enough to allow a uniform current spreading, but the cross-sectional area should be as small as possible in order to maximize the available area of the light emitting layer 5. In general, the cross-sectional area of individual first type vias 40 can be in the range from 1 to 3000 μm², such as 500 to 2000 μm² and the density of first type vias 40 can be in the range from 1 to 100 per mm², such as 10 to 70 per mm² The first type via 40 extends from the first electrode layer 13 to the first semiconductor layer 3, going through the light emitting lamination 51, the transparent conducting layer 7 and the conducting mesh 8. The first type via 40 needs to be electrically insulated from the light emitting layer 5, the second semiconductor layer 6, the transparent conducting layer 7, the reflective mesh 43 and the conducting mesh 8 because the first type via 40 only conducts current to the first semiconductor layer 3. The reflective stack of dielectric layers 10 has the function of insulating the first type via 40 from the light emitting layer 5, the second semiconductor layer 6, the transparent conducting layer 7, the reflective mesh 43 and the conducting mesh 8, and also serves as highly reflecting mirror for the light emitted at the light emitting layer 5. Therefore, the reflective stack of dielectric layers 10 is made to surround the first type via 40, where the reflective stack of dielectric layers 10 can be formed of alternating high and low refractive index dielectric materials with negligible optical absorption.

With reference to FIG. 5B, neither the first type openings 11 nor the second type openings 12 are shown. Despite that neither first nor second type openings 11 and 12 are shown, the first semiconductor layer 3 and the electrically conducting mesh 8 are electrically connected to first and second type via 40 and 41, respectively.

In FIG. 5C, the second electrode layer 14 is shown to be connected to the conducting mesh 8 through the second type via 41. The second type via 41 goes through at least one second type opening 12 of the reflective stack of dielectric layers 10 and extends from the upper surface of the second electrode layer 14 to the lower surface of the conducting mesh 8, therefore the conducting mesh 8, the reflective mesh 43, the transparent conducting layer 7, and the second electrode layer 14 are electrically connected. The reflective stack of dielectric layers 10 also serves as insulating layer between the second electrode layer 14 and the transparent conducting layer 7 in addition to reflecting the light from emitted at the light emitting layer 5.

FIG. 6 is a view illustrating a semiconductor light emitting device having texture 16 formed at the upper surface of the buffer layer 2 after removal of the native substrate 1 according to an exemplary embodiment of the present invention. The description of the same components that have already been described will be omitted.

In the semiconductor light emitting device according to the exemplary embodiment of the invention in FIG. 6, the buffer layer 2 forms the outer most layer in a direction in which emitted light moves. Therefore, texture 16 can be easily formed after the native substrate is removed and by using a known method such as wet chemical etching. In this case, the light from the light emitting layer 5 passes through the texture 16 formed at the upper surface of the buffer layer 2, and the light is extracted. The texture 16 results in an increase in light extraction efficiency. The texture 16 may be irregular or may be formed of periodically arranged features such as grooves or groove net with a dimension in the range from 0.1 to 2 μm.

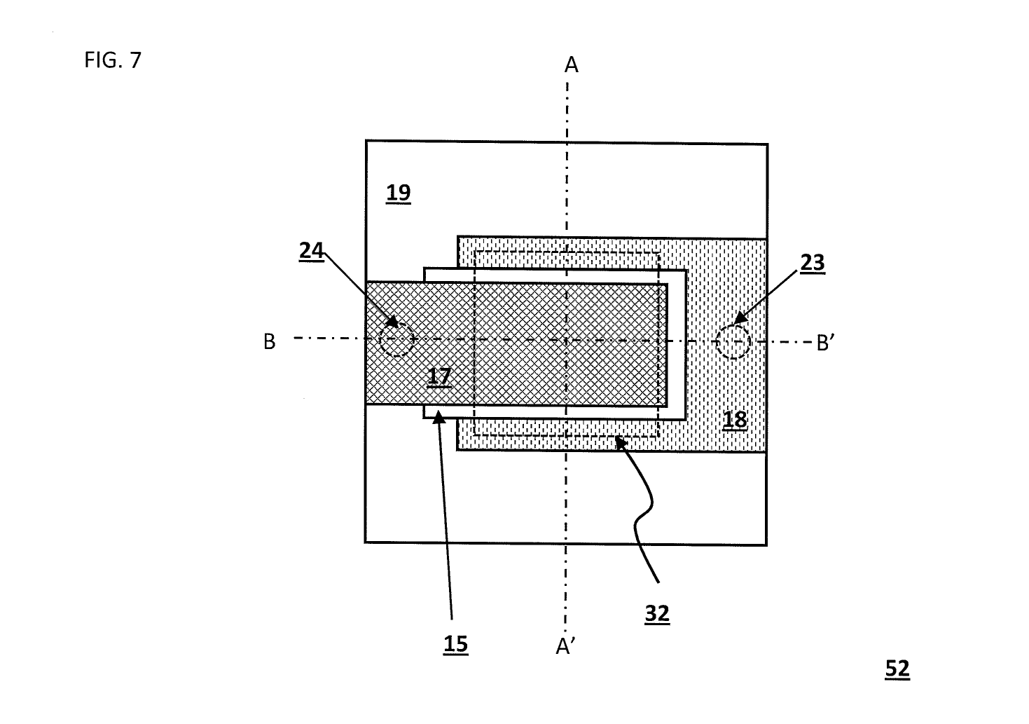

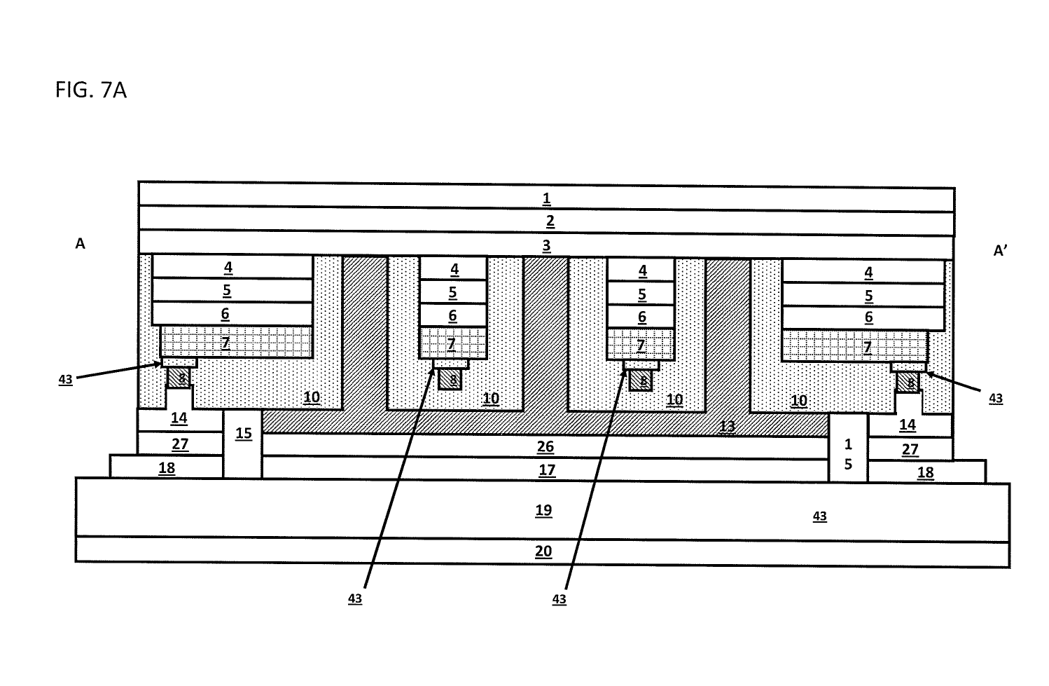

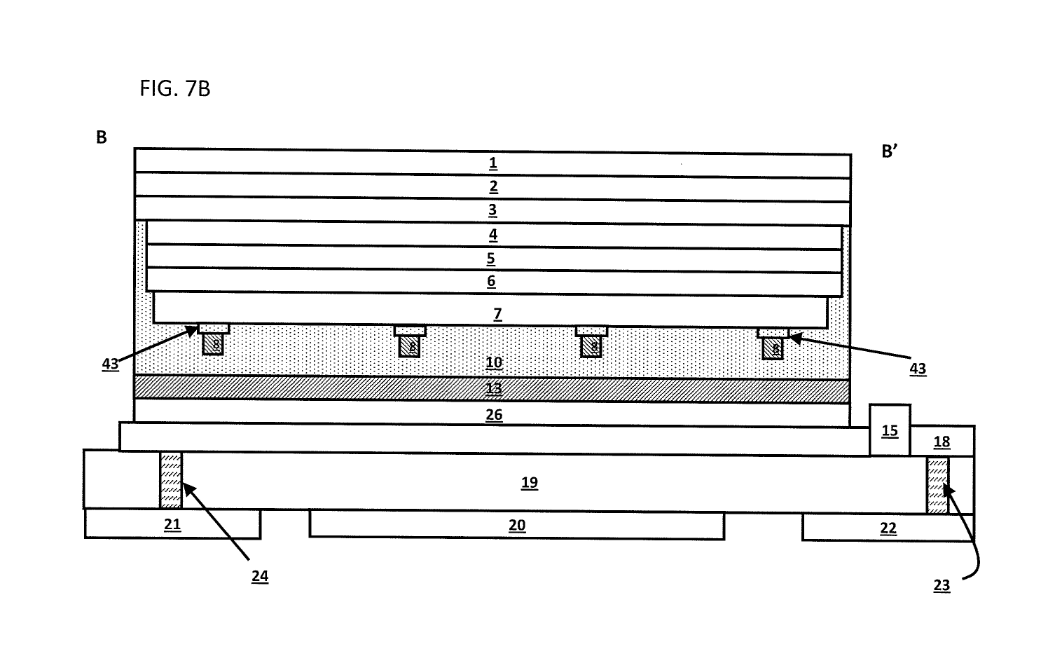

FIG. 7 is a top view illustrating a BREVMIRS LED package “type-A” 52 according to still another embodiment of the present invention. The BREVMIRS LED package “type-A” 52 includes an insulating submount 19, a first submount electrode 17, a second submount electrode 18, a first type submount via 23, a second type submount via 24, a first type bottom electrode 21, a second type bottom electrode 22, and a support pad 20. The insulating submount 19 may be formed of an insulating material with high coefficient of thermal conductivity such as AlN. The submount electrodes 17 and 18, the submount vias 23 and 24, as well as the first and second type bottom electrodes 21 and 22 and support pad 20 can be formed of metal. An insulating underfill 15 made of an electrically insulating material with a predetermined coefficient of thermal expansion matching that of the material used for the submount electrodes 17 and 18 is provided to electrically insulate the first submount electrode 17 from the second submount electrode 18. The BREVMIRS LED “type-A” 31 may be attached to the BREVMIRS LED package “type-A” 52, where the first and second electrode layers 13 and 14 are aligned with the first and second submount electrodes 17 and 18, respectively. The attachment of the semiconductor light emitting device to the BREVMIRS LED package “type-A” 52 can be performed by using a bonding method, for example a eutectic or a sintering bonding method can be used.

The first and second submount electrodes 17 and 18 are formed in contact with and electrically connected to the first and second electrode layers 13 and 14, respectively. The first and second submount electrodes 17 and 18 are formed on the top surface of the insulating submount 19 and are electrically isolated from each other. After a native substrate 1 such as sapphire or silicon carbide is used as growth substrate, the light emitting device can be bonded to the BREVMIRS LED package “type-A” 52 and the native substrate 1 then can be removed in order to allow the formation of texture 16 on the outer surface of the buffer layer 2 as shown in FIG. 6.

The BREVMIRS LED package “type-A” 52 has an upper surface in which first and second submount electrode 17 and 18, and insulating underfill 15 are formed, where the first and second submount electrode 17 and 18 are separated by a predetermined area which is filled or covered by the insulating underfill 15. A BREVMIRS LED “type-A” 31 is mounted on BREVMIRS LED package “type-A” 52, such that the first and second submount electrode 17 and 18 are in electrical contact with the first and second electrode layers 13 and 14, respectively. The semiconductor light emitting device corresponds to a BREVMIRS LED “type-A” 31 or BREVMIRS LED “type-A” without substrate 1 that has been described with reference to FIG. 4 and FIG. 6. The description of the same components having been described will be omitted.

FIG. 7A shows a cross section of the embodiment in FIG. 7 along the line AA,′ which includes a BREVMIRS LED “type-A” 31 as shown in FIG. 5C attached to BREVMIRS LED package “type-A” 52. The first and second electrode layers 13 and 14 are electrically connected to the first and second submount electrode 17 and 18, respectively. The first electrode layer 13 and the first submount electrode 17 are isolated from the second electrode layer 14 and the second submount electrode 18 by the insulating underfill 15 and the reflective stack of dielectric layers 10. The insulating submount 19 is supported by a support pad 20.

FIG. 7B shows a cross section of the embodiment in FIG. 7 along the line BB′, which includes a BREVMIRS LED “type-A” 31 attached to a BREVMIRS LED package “type-A” 52. The first electrode layer 13 is electrically connected to the first submount electrode 17. The second submount electrode 18 is electrically isolated from the first submount electrode 17 by the isolating underfill 15.

The first and second submount electrode 17 and 18 share the same plane, the second submount electrode 18 is isolated from the first submount electrode 17 by the insulating underfill 15. The first submount electrode 17 is electrically connected to a first type bottom electrode 21 through a first submount via 24 that penetrates through the insulating submount 19. Similarly, the second submount electrode 18 is electrically connected to a second type bottom electrode 22 through a second submount via 23, which also penetrates through the insulating submount 19. The first and second electrode layer 13 and 14, the first and second submount electrode 17 and 18, the support pad 20, the first and second type bottom electrode 21 and 22, and the first and second conductivity type submount via 23 and 24 may be formed of a metal or other suitable electrical and heat conducting materials. The support pad 20 is electrically isolated from the first and second type bottom electrodes 21 and 22, and serves only as a support for the package and also as a channel for heat transfer.

As shown on FIGS. 7, 7A and 7B, the BREVMIRS LED “type-A” 31 can be mounted to the BREVMIRS LED package “type-A” 52 in a single step by any known method known in the art, for example by a eutectic method and therefore without the need of wire bonding. Therefore, the BREVMIRS LED “type-A” 31 has a large contact area to the submount allowing a low thermal resistance, high light extraction efficiency and has a vertical structure. The structure formed by the transparent conducting layer 7, the reflective stack of dielectric layers 10, and the first and second electrode layers 13 and 14 provide a highly reflective mirror which will be referred here to as mesh opening mirror 35.

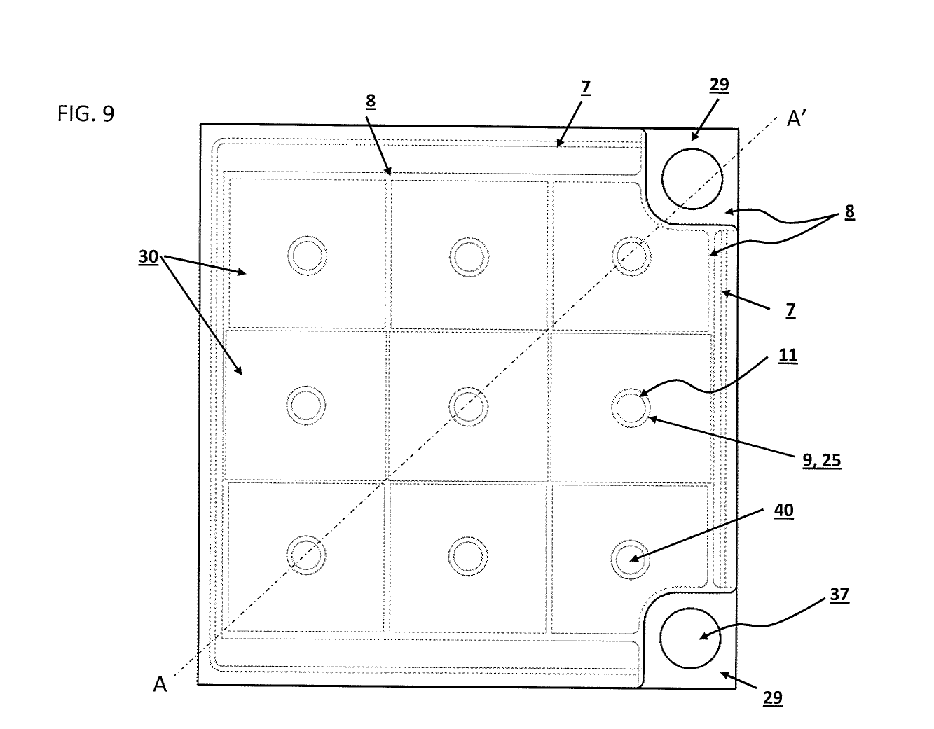

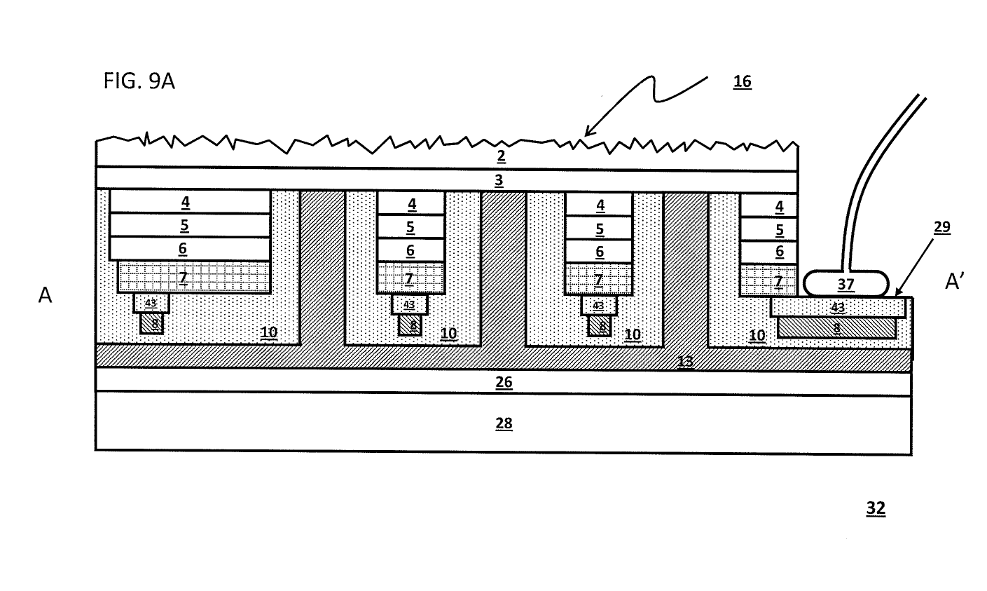

FIG. 8 shows an exploded view illustrating a BREVMIRS LED type “B” 32, including a BREVMIRS 36 structure as described in FIG. 3A according to an embodiment of the present invention with electrode contacts on opposite sides of the device. FIG. 9 shows a plan view of the LED chip with BREVMIRS shown in FIG. 8 as seen from the light emitting direction. Hereinafter, a description will be made with reference to FIGS. 8 and 9.

The BREVMIRS LED type “B” 32 includes an electrical conductive substrate 28, a first conductive bonding layer 26, a first electrode layer 13, a reflective stack of dielectric layers 10, a conducting mesh 8, a reflective mesh 43, a transparent conducting layer 7, a light emitting lamination 51, a first semiconductor layer 3, and a buffer layer 2. The reflective stack of dielectric layers 10 contains at least one first type opening 11. The reflective mesh 43 and or the conducting mesh 8 has at least one exposed area at the edge of the semiconductor light emitting device that serves as a second type electrode pad, and that can be connected to an external current source (not shown) through a wire bond 37. The reflective 43 and conducting mesh 8 is electrically connected to the transparent conducting layer 7, and the transparent conducting layer 7 is electrically connected to the second semiconductor layer 6. The transparent conducting layer 7 and the conducting mesh 8 are electrically isolated from the first electrode layer 13 and first type vias 40 by the reflective stack of dielectric layers 10. The first type vias 40 electrically connect the first electrode layer 13 to the first semiconductor layer 3. The conductive substrate 28 is electrically connected to the first electrode layer 13 by the first conductive bonding layer 26.

FIG. 9A shows a cross section view of a BREVMIRS LED “type-B” 32 as shown in FIG. 9, along the line AA′. The line AA′ is chosen in order to show a cross section of the BREVMIRS LED “type-B” 32, that includes first type openings 11 in the reflective stack of the dielectric layers 10, light emitting lamination holes 9, transparent conducting layer holes 25 and an exposed conductive mesh area 29 which is a part of conducting mesh 8.

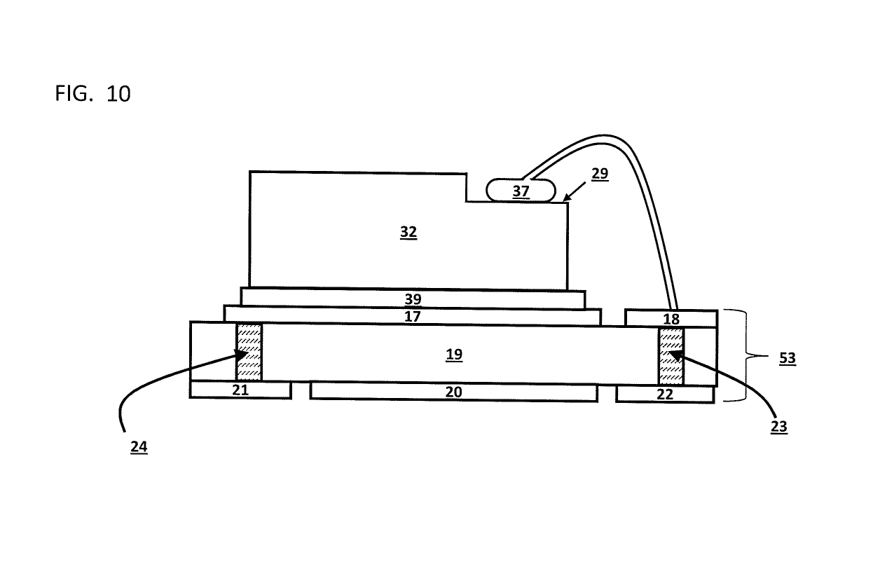

FIG. 10 shows a cross section view of BREVMIRS LED “type-B” 32 attached to a BREVMIRS LED “type-B” package 53. The BREVMIRS LED “type-B” package 53 includes an insulating submount 19, a first and a second submount electrode 17 and 18, a first and a second type bottom electrode 21 and 22, a first and a second type submount vias 23 and 24, and a support pad 20, similar with BREVMIRS LED package “type-A” 52. The BREVMIRS LED “type-B” 32 is attached to the BREVMIRS LED package “type-B” 52 with proper electrical connection by a die attachment layer 39. The first (second) submount electrode 17 (18) is electrically connected to the first (second) type bottom electrode 21 (22) by a first (second) type submount via 23 (24), respectively. The first and second submount electrodes 17 and 18, as well as the support pad 20, and first and second type bottom electrodes 21 and 22, are electrically insulated from each other by a predetermined distance and by the insulation submount 19. The BREVMIRS LED “type-B” 32 is further connected to the second submount electrode 18 by a wire bond 37. The wire bond 37 electrically connects the exposed conductive mesh area 29 of the BREVMIRS LED “type-B” 32 to the second submount electrode 18. The first and second type bottom electrode 21 and 22 are connected to an external current source (not shown) according to the corresponding electroconductivity of each contact, respectively.

The exposed conductive mesh area 29 which is electrically connected to a second semiconductor layer 6 has a smaller size than the contact in a conventional light emitting device. For example, the size of the exposed conductive mesh area 29 can be in the range from 0.001 to 0.02 mm², where smaller size is desired in order to take less area away from light emitting layer 5.

Thus, the BREVMIRS LED “type-B” 32 having a high LEE, large area of light emitting layer 5, and high optical efficiency can be mounted on a BREVMIRS LED “type-B” package 53 without the need of an alignment process, it requires a relatively simple wire bonding process.

As described above, according to exemplary embodiments of the invention, the BREVMIRS-LED “type-A” 31 and “type-B” 32 ensure the maximum area of the light emitting layer, are free of thermal resistance of the native substrate, and contain a mirror with reflectivity higher than 95% with a design that provides a uniform current density distribution due to the via through mesh-cell design.

The main differences between the BREVMIRS LED “type-A” 31 and “type-B” 32 may offer a better advantage depending on the importance of a more efficient chip or a lower cost chip. For example the BREVMIRS LED “type-A” 31 does not require a conductive substrate and may offer a slightly larger active region area and therefore slightly higher IQE in exchange of the need of an alignment process for die attach. On the other hand, the BREVMIRS LED “type-B” 32 can be bonded to a package without an alignment process and use a relatively low cost wire bonding method, but at the cost of slightly smaller active region and thus slightly lower IQE.

BREVMIRS LEDs can be manufactured with conventional techniques already used for LEDs, therefore, for both BREVMIRS LED types, mass production can be achieved at low cost and high optical output.

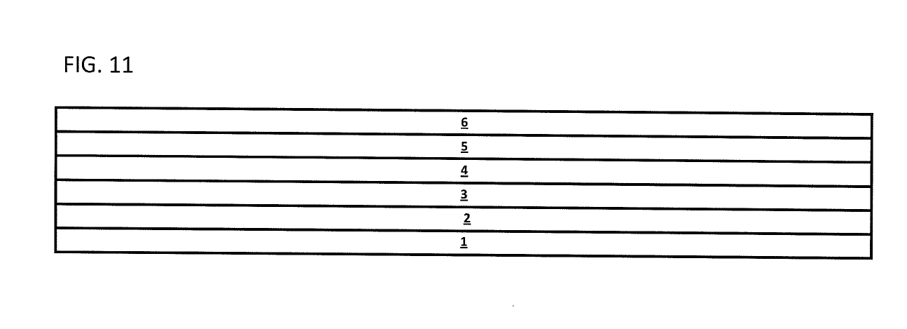

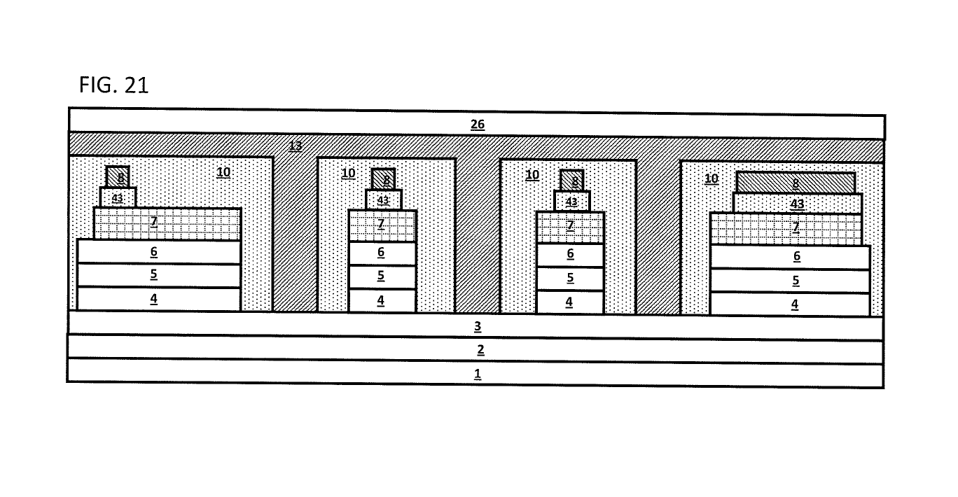

FIGS. 11-24 are cross-sectional views illustrating an exemplary method of BREVMIRS LED type-A and B fabrication in accordance with the teachings of the present invention, where FIGS. 11 to 16 show common steps for BREVMIRS LED “type-A” and “-B”, FIGS. 17 to 19 and FIG. 7A for “type-A” and FIGS. 20 to 24 and FIG. 9A for “type-B”. FIGS. 11-18 and 20-23 illustrate fabrication at the wafer level and FIGS. 7A, 19 and 9A at the chip level.

FIG. 11 is a cross-sectional view of a native substrate 1 having a buffer layer 2, a first semiconductor layer 3 and 4, a light emitting layer 5 and a second semiconductor layer 6 formed thereon, forming a semiconductor based heterostructure. The buffer layer 2 (such as unintentionally doped GaN) is deposited on the native substrate 1 to facilitate the deposition of the subsequent semiconductor layers. The buffer layer 2 is utilized to reduce the stress and/or strain (e.g., due to thermal or lattice mismatch between native substrate and the semiconductor layer 3 and the light emitting lamination 51 formed by first semiconductor layer 3 and 4, light emitting layer 5 and second semiconductor layer 6) in the semiconductor heterostructure, which typically has a single crystal structure. The deposition or growth of the above mentioned layers to form a semiconductor heterostructure may be provided through any selected process as known or becomes known in the art and or may be proprietary to the device fabricator. In an exemplary embodiment, a light emitting region comprised of first semiconductor layer 3,4, light emitting layer 5, and second semiconductor layer 6 are deposited sequentially over native substrate 1. Note that in order to fabricate a BREVMIRS LED the order of the steps listed below is not limited to this particular sequence and that the fabrication of the BREVMIRS LED can be adapted by modifications to the order of such steps, and the depositing, patterning, and etching of various layers can conducted by any suitable method known in the art.

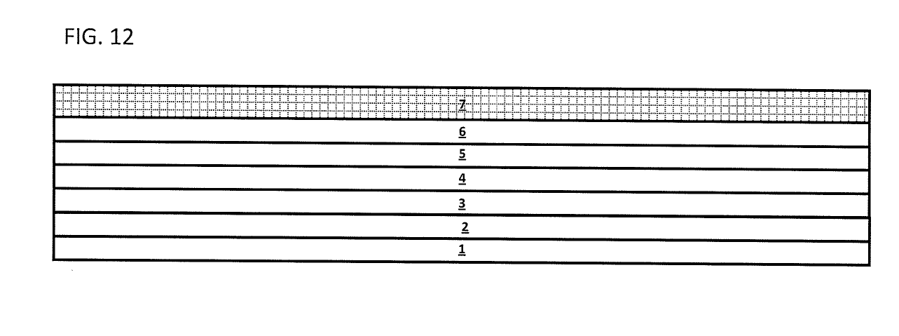

A transparent conducting layer 7 is deposited on the second semiconductor layer 6 forming an ohmic contact, as illustrated in FIG. 12.

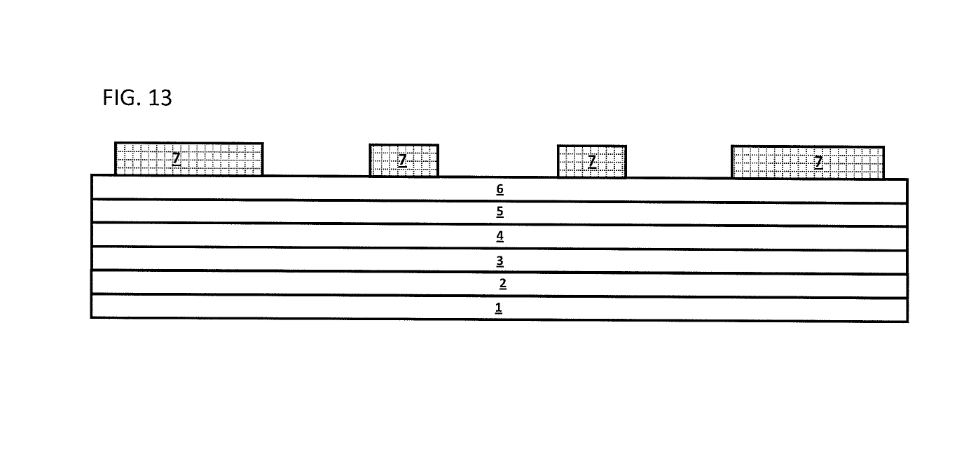

The transparent conductive layer 7 is patterned and etched to form a plurality of openings 25 exposing the second semiconductor layer 6 with a predetermined pattern, as illustrated in FIG. 13.

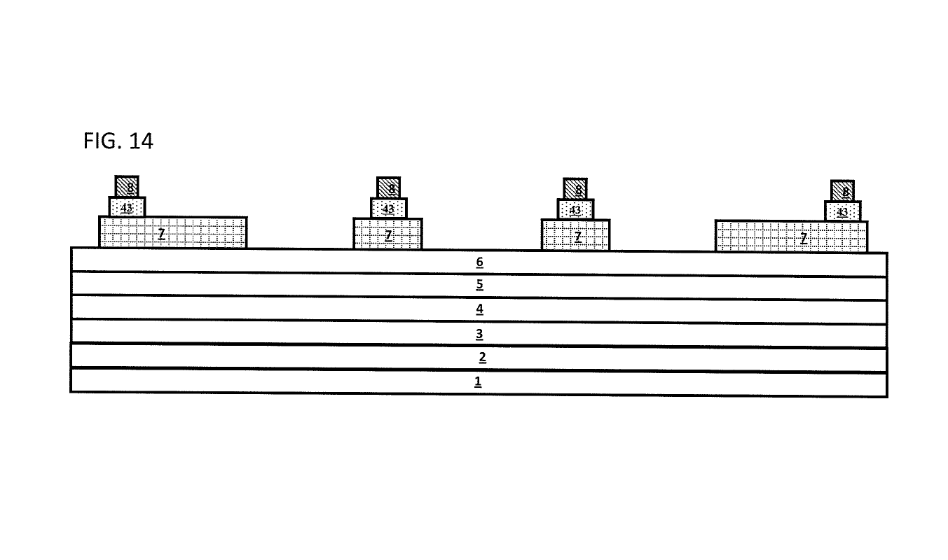

As shown in FIG. 14, a reflective mesh 43 is deposited on the transparent conducting layer 7. The reflective mesh 43 may contain aluminum, silver and nickel or a combination of them and a total thickness in the range of 1 to 2000 nm, such as 5 to 1000 nm, 10 to 200 nm, preferably 20 to 100 nm.

Sequentially, a conducting mesh 8 is deposited on top of the reflective mesh 43. The conducting mesh 8 may contain gold or other highly electrically conductive metal, the conducting mesh 8 is formed in conformal in shape to the reflective mesh 43 and the thickness of the conducting mesh 8 in the range of 500 to 5000 nm, preferably in the range of 2000 to 4000 nm, such as 2500 to 3500 nm

Specifically, the above reflective mesh 43 and conducting mesh 8 can be formed as follows: a layer of the reflective metal, such as aluminum, silver and nickel or a combination of layers of these metals is deposited on transparent conducting layer 7; then, a conducting layer of gold or other highly electrically conductive metal is deposited on the reflective metal layer; the conducting layer and the reflective metal layer are patterned and etched to form the conducting mesh 8 and the reflective mesh 43.

Alternatively, the reflective mesh 43 can be deposited directly on the second semiconductor layer 6, then the conducting mesh 8 is deposited on top of the reflective mesh 43, and sequentially the transparent conducting layer 7 is deposited over the conducting mesh 8 and the reflective conductive mesh openings 30 in order to obtain a structure as shown in FIG. 3B.

Specifically, the above reflective mesh 43 and conducting mesh 8 can be formed as follows: a layer of the reflective metal, such as aluminum, silver and nickel or a combination of layers of these metals is deposited on second semiconductor layer 6; then, a conducting layer of gold or other highly electrically conductive metal is deposited on the reflective metal layer; the conducting layer and the reflective metal layer are patterned and etched to form the conducting mesh 8 and the reflective mesh 43; then transparent conducting layer 7 is deposited on the conducting mesh 8, the reflective mesh 43, and the second semiconductor layer 6.

It should be understood that the reflective mesh 43 is optional and not necessarily to be conformal with the conducting mesh 8 as long as it can improve the reflectivity of the conducting mesh 8.

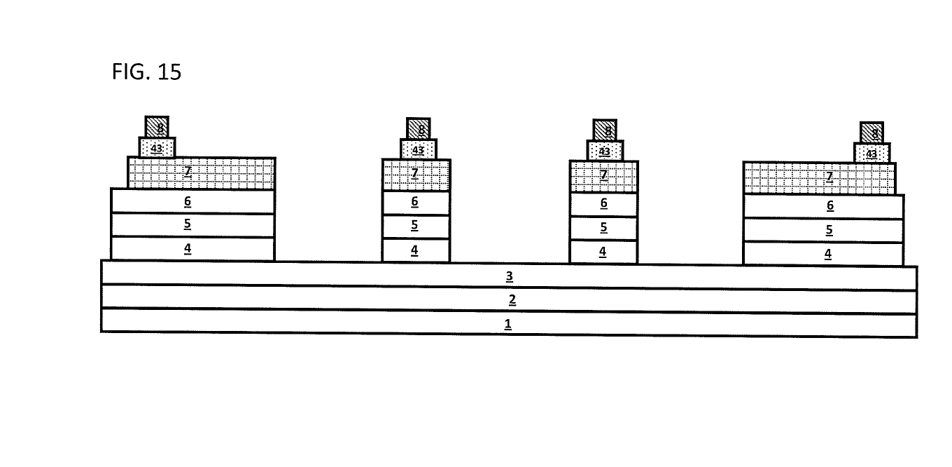

After the formation of conducting mesh 8 and transparent conducting layer 7, the first semiconductor layer 4, light emitting layer 5 and second semiconductor layer 6 are etched to form a plurality of openings 9 exposing, but preferably not extending into, the first semiconductor layer 3, as illustrated in FIG. 15.

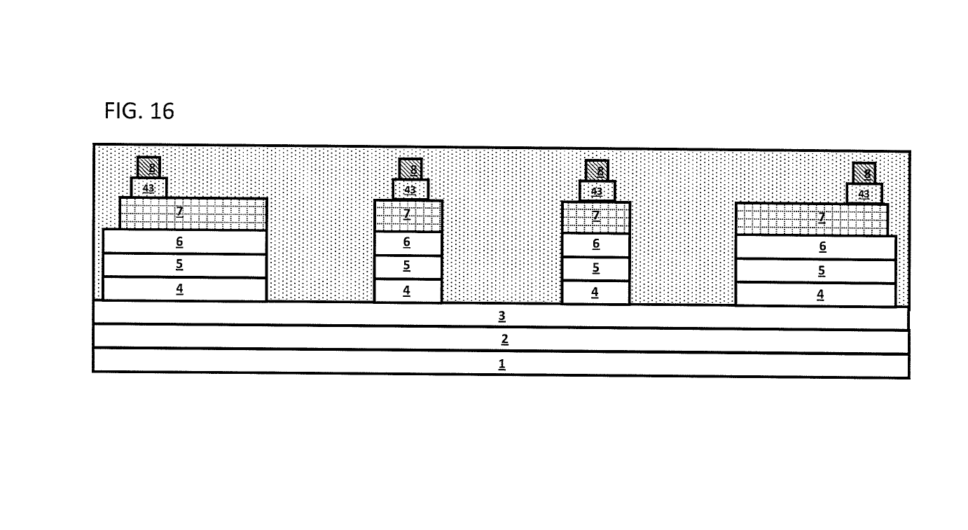

Through appropriate or standard deposition method as known in the art, such as by electron beam-induced physical vapor deposition, a stack of alternating transparent dielectric layers with first and second index of refraction is deposited on the first semiconductor layer 3, the transparent conducting layer 7 and the conducting mesh 8, as illustrated in FIG. 16. The index of refraction of the materials forming the stack of dielectric layers is chosen such that the first index of refraction is lower than the second index of refraction at the wavelength of the light emitted by the light emitting layer, as an example SiO₂ is suitable as a material with first index of refraction and TiO₂ as a material with second index of refraction. The first layer of the reflective dielectric layer stack 10 adjacent to the transparent conducting layer 7 has a first index of refraction.

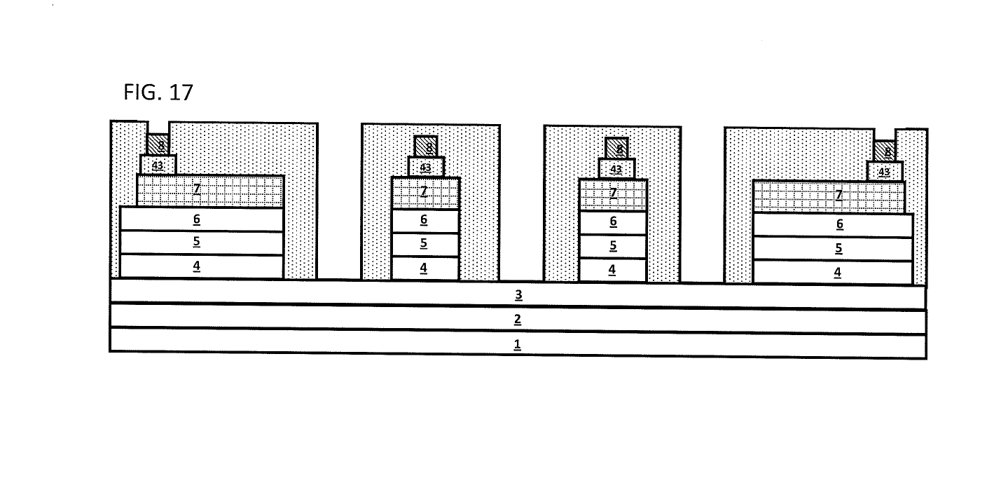

In order to make a BREVMIRS LED “type-A”, the stack of dielectric layers 10 is partially etched to form second type openings 12 exposing conducting mesh 8 at the peripheral part of the structure shown in FIG. 17 and to form first type openings 11 exposing the first semiconductor layer 3 within the previously etched openings 9, as illustrated in FIG. 17.

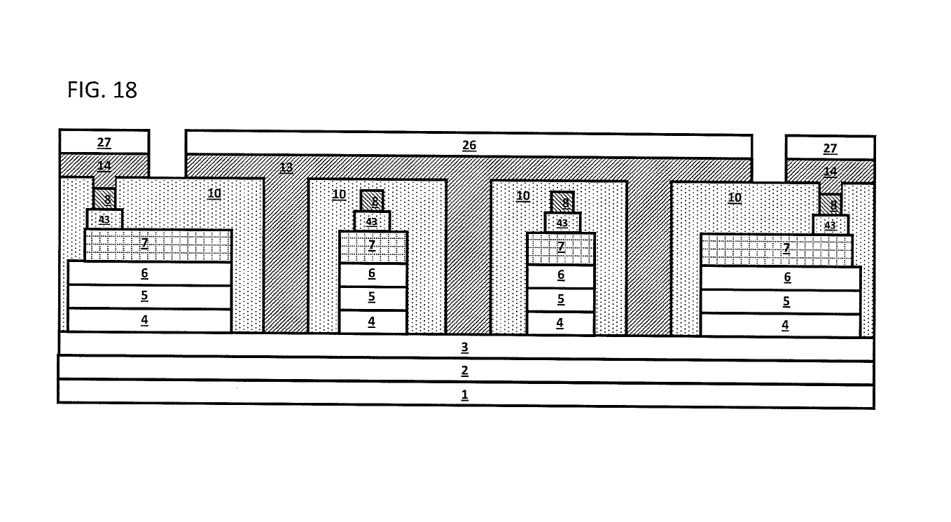

A layer of reflective conducting material is deposited on the stack of dielectric layers 10 filling the first type openings 11 and the second type openings 12, and is patterned and etched to form a first reflective electrode layer 13 and a second reflective electrode layer 14 electrically isolated from the first reflective electrode layer 13. A first conductive bonding layer 26 and a second conductive bonding layer 27 can be deposited on the first reflective electrode layer 13 and the second reflective electrode layer 14, respectively. The portion of the first reflective electrode layer 13 that fills the first type openings 11 in the stack of dielectric layers 10 forms vias 40 which are electrically connected to the first semiconductor layer 3, and the portion of the second reflective electrode layer 14 that fills the second type openings 12 in the stack of dielectric layers 10 forms vias 41 which are electrically connected to the conducting mesh 8, as illustrated in FIG. 18.

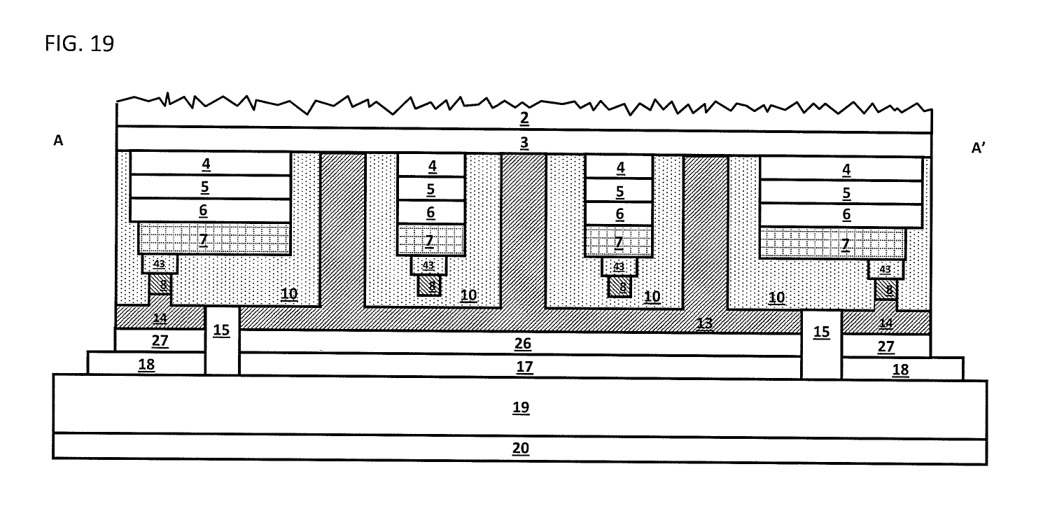

In an embodiment, the chip structure shown in FIG. 18 is bonded to a submount by ultrasonic welding for example such that the first and second electrodes 17 and 18 of the submount are in electrical contact with the first and second conductive bonding layer 26 and 27 on the chip structure, respectively, as illustrated in FIGS. 19 and 7A in a different cross sectional view. This finalizes the fabrication of a BREVMIRS-LED “type-A” with substrate.

In an embodiment, the substrate 1 may be removed by laser lift off for example, and the outer surface of the buffer layer 2 is textured by an alkaline etch for example, as illustrated in FIG. 19, this finalizes the fabrication of a BREVMIRS LED “type-A” with the substrate removed.

Since the first six steps are common in the fabrication of BREVMIRS LED “type-A” and “type-B”, the first six steps for the BREVMIRS LED “type-B” are omitted below and the following steps relate to the fabrication of a BREVMIRS LED “type-B”.

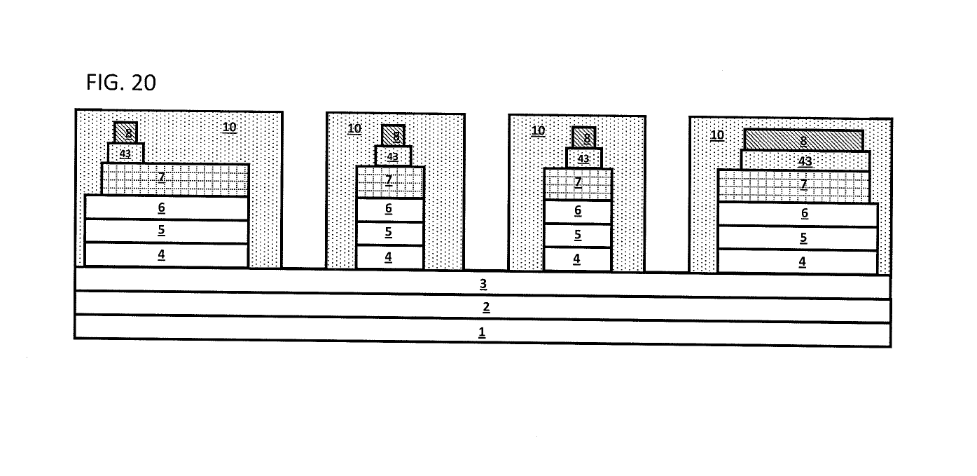

In an embodiment, the stack of dielectric layers 10 is partially etched to form first type openings 11 exposing the first semiconductor layer 3 within the previously etched openings 9, as illustrated in FIG. 20.

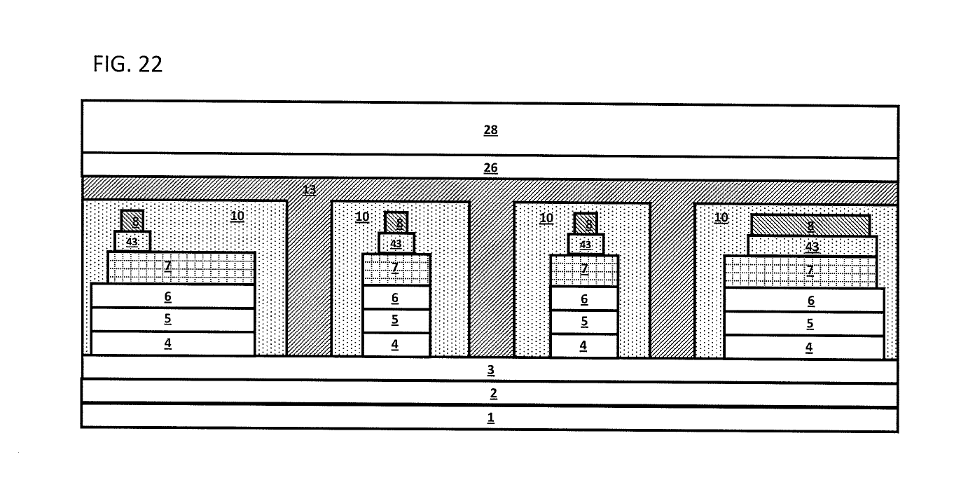

A first reflective electrode layer 13 is deposited on the stack of dielectric layers 10 and fills the first type openings 11. Using a known method to the art, a first conductive bonding layer 26 is deposited on the first electrode layer 13, as shown in FIG. 22.

A conductive substrate 28, such as doped silicon for example, is bonded to the first conductive bonding layer 26 by using a known method to the art, forming an ohmic contact with the first conductive bonding layer 26, as illustrated in FIG. 22.

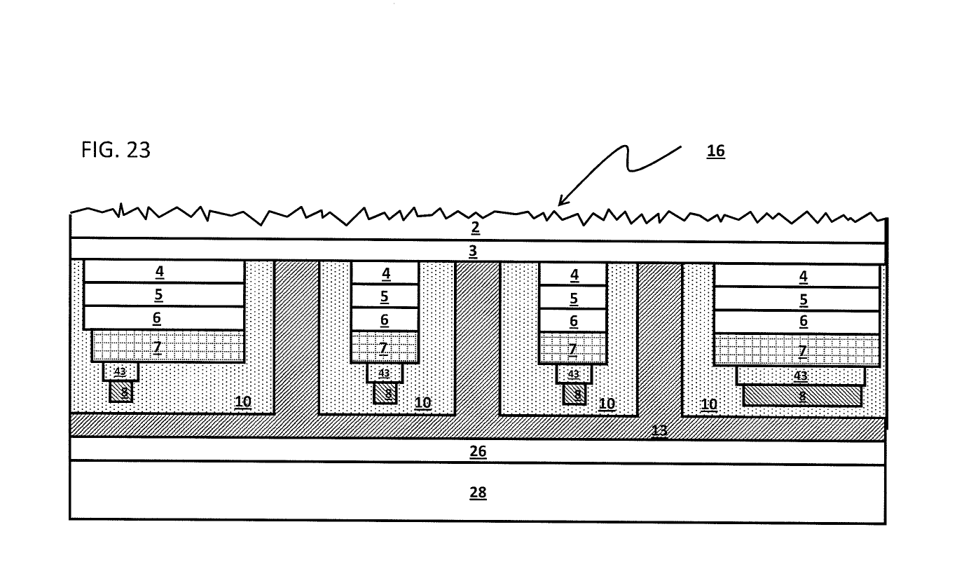

The wafer as shown in FIG. 22 is flipped and, with the conductive substrate 28 as support, the native substrate 1 is removed, after which a texture 16 is formed on the outer surface of the buffer layer 2 using a known method to the art, for example by alkaline etching, as illustrated in FIG. 23.

Next, a via structure is formed from the buffer layer side 2 using a known method, such as dry etch, exposing a portion of the conducting mesh 8, as illustrated in FIG. 9A. Then the wafer is cut into individual chips and the BREVMIRS LED “type-B” can be mounted on a submount by eutectic bonding for instance, as shown in FIG. 10.

Therefore, according to the embodiments of the invention, mass production of light emitting devices with high LEE and low thermal resistance can be realized at low cost and high reliability. While the present invention has been shown and described in connection with the exemplary embodiments, it will be apparent to those skilled in the art that modifications and variations can be made without departing from the spirit and scope of the invention as defined by the appended claims. Components or features described in any embodiment can be combined into the structure described in any other embodiment as long as no conflict exists for such combination.

What is claimed is:

1. A buried reflective electrode structure for a light emitting device, comprising:
a first electrode layer having at least one first type via extending from one surface thereof;
a reflective stack of dielectric layer;
a reflective mesh;
a conducting mesh; and
a transparent conducting layer;
wherein the reflective stack of dielectric layer is positioned between the first electrode layer and the transparent conducting layer and electrically insulates the first electrode layer from the transparent conducting layer, and the reflective and conducting mesh is positioned adjacent to and electrically connected with the transparent conducting layer;
the first type via penetrates through the reflective and conducting mesh, the transparent conducting layer, and the reflective stack of dielectric layer, and the first type via is electrically insulated from the reflective and conducting mesh and the transparent conducting layer.

2. The buried reflective electrode structure of claim 1, wherein the first electrode layer has a plurality of first type vias extending from one surface thereof, the reflective stack of dielectric layer has a plurality of first type via holes, the reflective and conducting mesh has a plurality of openings, the transparent conducting layer has a plurality of holes; the first type vias penetrate the conducting mesh through corresponding openings in the reflective and conducting mesh, the transparent conducting layer through corresponding holes in the transparent conducting layer, and the reflective stack of dielectric layer through corresponding first type via holes of the reflective stack of dielectric layer; and the first type vias are electrically insulated from the reflective and conducting mesh and the transparent conducting layer.

3. The buried reflective electrode structure of claim 1, wherein said reflective stack of dielectric layer surrounds and is in direct contact with entire sidewall surfaces of the first type vias except for a top surface of the first type vias.

4. The buried reflective electrode structure of claim 1, wherein the reflective and conducting mesh is located in between the transparent conducting layer and the reflective stack of dielectric layer.

5. The buried reflective electrode structure of claim 1, wherein the reflective and conducting mesh is covered with a thin transparent conducting layer of silver or nickel on a surface thereof away from the first electrode layer.

6. The buried reflective electrode structure of claim 1, wherein said reflective stack of dielectric layer comprises a first dielectric layer and a second dielectric layer with the first dielectric layer being adjacent to the transparent conducting layer, wherein the first dielectric layer has a first index of refraction, the second dielectric layer has a second index of refraction, and the first index of refraction is lower than the second index of refraction.

7. The buried reflective electrode structure of claim 6, wherein said reflective stack of dielectric layer comprises a plurality of pairs of the first and second dielectric layers with the first and second dielectric layers being alternately arranged.

8. The buried reflective electrode structure of claim 6, where said first dielectric layer comprises silicon dioxide (SiO₂) or magnesium fluoride (MgF₂), and said second dielectric layer comprises titanium dioxide (TiO₂), or niobium pentoxide (Nb₂O₅), or niobium dioxide (NbO₂).

9. The buried reflective electrode structure of claim 1, further comprising a second electrode layer formed co-plane with and electrically insulated from the first electrode layer, and electrically connected with the conducting mesh.

10. The buried reflective electrode structure of claim 1, wherein said transparent conducting layer comprises indium tin oxide (ITO), zinc oxide (ZnO), grapheme, or indium gallium zinc oxide (IGZO).

11. The buried reflective electrode structure of claim 1, wherein a percentage ratio of area of the conducting mesh to area of the transparent conducting layer is from 10% to 20%.

12. The buried reflective electrode structure of claim 9, wherein the second electrode layer has at least one second type via extending from one surface thereof, the reflective stack of dielectric layer has at least one second type via hole, and the second type via penetrates the reflective stack of dielectric layer through the second type via hole and contacts the conducting mesh.

13. A light emitting device with a buried reflective electrode structure comprising:
a first semiconductor layer (a);
a first semiconductor layer (b);
a light emitting layer;
a second semiconductor layer, wherein the first semiconductor layer (b), the light emitting layer, and the second semiconductor layer form a light emitting lamination, the light emitting layer is located between the first semiconductor layer (b) and the second semiconductor layer, and the first semiconductor layer (b) is located between the light emitting layer and first semiconductor layer (a);
a transparent conducting layer formed on and electrically connected with the second semiconductor layer;
a reflective mesh arranged on and electrically connected with the transparent conductive layer;
a conductive mesh deposited and electrically connected on the reflective mesh;
a reflective stack of dielectric layers disposed over the transparent conducting layer and the conducting mesh;
a first electrode layer and a second electrode layer deposited on the reflective stack of dielectric layers, wherein the first electrode layer is insulated from the second electrode layer;
wherein said first electrode layer is electrically connected to the first semiconductor layer (a) by one or more first type via electrically isolated from said second semiconductor layer and the light emitting layer;
wherein the first type via passes through an opening of the reflective and conducting mesh, a hole in the reflective stack of dielectric layers, a hole in the transparent conducting layer and a hole in the light emitting lamination; and
wherein the second conductivity type electrode layer is electrically connected to the reflective and conducting mesh by one or more second type via extending through the stack of reflective layers.

14. The device of claim 13, wherein the size of the holes in the reflective stack of dielectric layers, the transparent conducting layer and the light emitting lamination for accommodating the first type via has the following order: hole in the transparent conducting layer≧hole in the light emitting lamination>hole in the reflective stack of dielectric layers.

15. The device of claim 13, wherein said first conductivity type layer, said second conductivity layer, and said light emitting layer are primarily based on InₓAl_{y}Ga_{(1-x-y)}N (0≦x≦1, 0≦y≦1, 0≦x+y≦1).

16. The device of claim 13, wherein the first and second electrode layers are co-plane.

17. A light emitting device with a buried reflective electrode structure comprising:
a buffer layer;
a first semiconductor layer (a);
a first semiconductor layer (b);
a light emitting layer;
a second semiconductor layer, wherein the first semiconductor layer (b), the light emitting layer, and the second semiconductor layer form a light emitting lamination, the light emitting layer is located between the first semiconductor layer (b) and the second semiconductor layer, and the first semiconductor layer (b) is located between the light emitting layer and first semiconductor layer (a);
a transparent conducting layer formed on and electrically connected with the second semiconductor layer;
a reflective mesh arranged on and electrically connected to the transparent conductive layer, wherein the reflective mesh has an area exposed by the transparent conducting layer, the light emitting lamination, the first semiconductor layer (a), and the buffer layer;
a conducting mesh arranged on and electrically connected to the reflective mesh;
a reflective stack of dielectric layers disposed over the transparent conducting layer, reflective mesh and the conducting mesh;
a first electrode layer deposited on the reflective stack of dielectric layers;
a first conductive bond material deposited on the first electrode layer on the opposite side to the reflective stack of dielectric layers;
a conductive substrate attached to the first electrode layer by the first conductive bond material; and
wherein said first electrode layer being connected to the other of said first semiconductor layer by an electrically conducting first type via electrically isolated from said second semiconductor layer and light emitting layer.

18. The device of claim 17, wherein the first and second electrodes are on opposed sides of the light emitting device.

19. The device of claim 17, wherein the exposed area of the conducting mesh is located at the edge of the light emitting device.

20. The device of claim 17, wherein a texture is formed on the outermost surface of the buffer layer.
